(19) United States
(12) Patent Application Publication
(10) Pub. No.: US 2025/0349598 A1
(43) Pub. Date: Nov. 13, 2025

(54) SEMICONDUCTOR DEVICE AND RELATED METHODS

(71) Applicant: Taiwan Semiconductor Manufacturing Company, Ltd., Hsinchu (TW)

(72) Inventors: Ta-Chun Lin, Hsinchu (TW); Fu-Hsiang Su, Zhubei City (TW); Chia-Hao Kuo, Taoyuan City (TW); Jhon Jhy Liaw, Hsinchu County (TW)

(21) Appl. No.: 19/279,546

(22) Filed: Jul. 24, 2025

Related U.S. Application Data
(63) Continuation of application No. 18/773,923, filed on Jul. 16, 2024.
(60) Provisional application No. 63/626,626, filed on Jan. 30, 2024.

(51) Int. Cl. H01L 21/762; H10D 30/01; H10D 30/43; H10D 30/67; H10D 62/10; H10D 64/01

(52) U.S. Cl. CPC H01L 21/76224; H10D 30/014; H10D 30/43; H10D 30/6735; H10D 30/6757; H10D 62/121; H10D 64/017

(57) ABSTRACT

A method of fabricating a semiconductor device includes providing a partially-fabricated semiconductor device including a dummy gate structure disposed over a semiconductor layer stack. In some embodiments, the method further includes removing the dummy gate structure and at least a portion of each semiconductor layer of the semiconductor layer stack to form a trench. In some examples, the method further includes forming one or more refill layers in a bottom portion of the trench and forming one or more refill layers in a top portion of the trench over the bottom portion of the trench. In some embodiments, the one or more refill layers in the top and bottom portions of the trench respectively define top and bottom portions of an isolation structure. In some examples, at least one refill layer of respective ones of the top and bottom portions of the isolation structure have a different material composition.

### CROSS-REFERENCE TO RELATED APPLICATIONS

This application is a continuation of U.S. patent application Ser. No. 18/773,923, filed Jul. 16, 2024, which claims the benefit of U.S. Provisional Application No. 63/626,626, filed Jan. 30, 2024, the entireties of which are incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As one example, to continue to provide the desired scaling and increased density for semiconductor devices in advanced technology nodes, continued reduction of the contacted poly pitch (CPP) (or “gate pitch”) is necessary. In at least some existing implementations, a continuous poly on diffusion edge (CPODE) process has been used to scale the CPP. By way of example, a CPODE process may be used to provide isolation between neighboring active regions (e.g., device regions including source, drain, and gate structures). However, in some existing implementations, CPODE regions may be formed in such a way that induces undesirable leakage current, thereby undermining the CPODE region's ability to provide electrical isolation, and more generally, compromising device performance and reliability. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified top-down layout view of a multi-gate device, according to one or more aspects of the present disclosure;

FIGS. 2A and 3A provide cross-sectional views of embodiments of exemplary semiconductor devices along a plane substantially parallel to a plane defined by section YY′ of FIG. 1, in accordance with some embodiments;

FIGS. 2B and 3B provide cross-sectional views of embodiments of the exemplary semiconductor devices along a plane substantially parallel to a plane defined by section XX′ of FIG. 1, in accordance with some embodiments;

FIG. 4 is a flow chart of a method of fabricating a multi-gate device according to one or more aspects of the present disclosure;

FIGS. 5, 6, 7, and 8 provide cross-sectional views of an embodiment of a semiconductor device along a plane substantially parallel to a plane defined by section XX′ of FIG. 1, according to various stages of the method of FIG. 4;

FIGS. 9A, 9B, 10, 11, 12, 13, 14, and 15 provide cross-sectional views of alternative embodiments of various semiconductor devices along a plane substantially parallel to a plane defined by section XX′ of FIG. 1, fabricated in accordance with various embodiments of the method of FIG. 4;

FIG. 16 is a flow chart of another method of fabricating a multi-gate device according to one or more aspects of the present disclosure;

FIGS. 17, 18, 19, 20, and 21 provide cross-sectional views of an embodiment of a semiconductor device along a plane substantially parallel to a plane defined by section XX′ of FIG. 1, according to various stages of the method of FIG. 16; and

FIGS. 22, 23, 24, 25, 26, 27, and 28 provide cross-sectional views of alternative embodiments of various semiconductor devices along a plane substantially parallel to a plane defined by section XX′ of FIG. 1, fabricated in accordance with various embodiments of the method of FIG. 16.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

It is also noted that the present disclosure presents embodiments in the form of multi-gate transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as fin field-effect transistors (FinFETs), on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanowires/nanosheets) associated with a single, contiguous gate structure. However, one of ordinary skill would recognize that the teaching can apply to a single channel (e.g., single nanowire/nanosheet) or any number of channels. One of ordinary skill may recognize other examples of semiconductor devices that may benefit from aspects of the present disclosure. For example, in some cases, aspects of the present disclosure may be equally applicable to planar transistor devices, forksheet devices, complementary FET (CFET) devices, and the like.

Continuing to provide the desired scaling and increased density for semiconductor devices in advanced technology nodes calls for scaling of the contacted poly pitch (CPP) (or “gate pitch”). In at least some existing implementations, a continuous poly on diffusion edge (CPODE) process has been used to scale the CPP. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation region (or dielectric plug) between neighboring active regions, and thus neighboring transistors, by performing a dry etching process along an active edge (e.g., at a boundary of adjacent active regions) to form a cut region and filling the cut region with a dielectric, such as silicon nitride (SiN).

By way of example, and in accordance with at least one implementation of a CPODE process, a CPODE dry etching process may be performed along an active edge that includes a dummy device structure (e.g., such as a dummy gate stack and a plurality of channels). In particular, the CPODE dry etching process may be performed to form a cut region along the active edge, the cut region including a trench formed along the active edge. After forming the trench in the cut region, a refill process is performed, where a refill dielectric (e.g., such as SiN or a SiN-like dielectric) is used to fill the trench in the cut region. In some cases, an interface between the semiconductor substrate and the refill dielectric may induce fixed charge, which in turn may lead to undesirable leakage current. In other words, the refill dielectric (e.g., SiN or SiN-like dielectric) may attract charge, and the unwanted leakage current may flow in the underlying semiconductor substrate. As a result, device performance and reliability of a transistor formed in an adjacent active region may be degraded. In some examples, a thick fixed-charge-free layer (e.g., such as an SiO layer or an SiO-like layer) may be formed as a liner layer, within the trench in the cut region, prior to deposition of the SiN refill dielectric to try to mitigate the leakage current between the semiconductor substrate and the refill dielectric. However, in various cases, the thick fixed-charge-free layer may be easily consumed by exposure to a post wet clean process (e.g., such as may be performed during removal of a dummy poly gate), resulting in the formation of voids that can lead to yield or reliability issues. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and related methods of forming a CPODE structure (or dielectric plug), with multiple dielectric layers of varying material composition stacked at least partially in a vertical direction, to provide leakage current reduction (e.g., at the interface between the substrate and the bottom of the CPODE structure). In an example, the CPODE refill material used to refill a bottom portion of the CPODE structure (bottom CPODE refill material) may include a single layer or multiple layers and is selected to include a fixed-charge free material. In some embodiments, the CPODE refill material and/or number of layers used to refill a top portion of the CPODE structure (top CPODE refill material) may be different from the bottom CPODE refill material and/or number of layers. To be sure, in some cases the bottom CPODE refill material and the top CPODE refill material may both include at least one layer formed of the same material. In some embodiments, the bottom CPODE refill material includes an SiO-like material, and the top CPODE refill material includes an SiN-like material. In some embodiments, the bottom CPODE refill material may be buried below a plane defined by a top surface of a neighboring shallow trench isolation (STI) region, and the overall depth of the disclosed CPODE structure may be deeper than (or in some cases, shallower than) neighboring STI regions. In various examples, the bottom CPODE refill material is selected to provide leakage current reduction, and the top CPODE refill material is selected to mitigate loss (e.g., such as may occur in existing implementations during removal of a dummy poly gate). By employing the disclosed CPODE process and related structure(s), device performance and reliability of transistors formed in the adjacent active regions will be enhanced. Moreover, the disclosed embodiments are compatible with existing processes and can be implemented with minimal additional cost. Other embodiments and advantages will be evident to those skilled in the art upon reading the present disclosure.

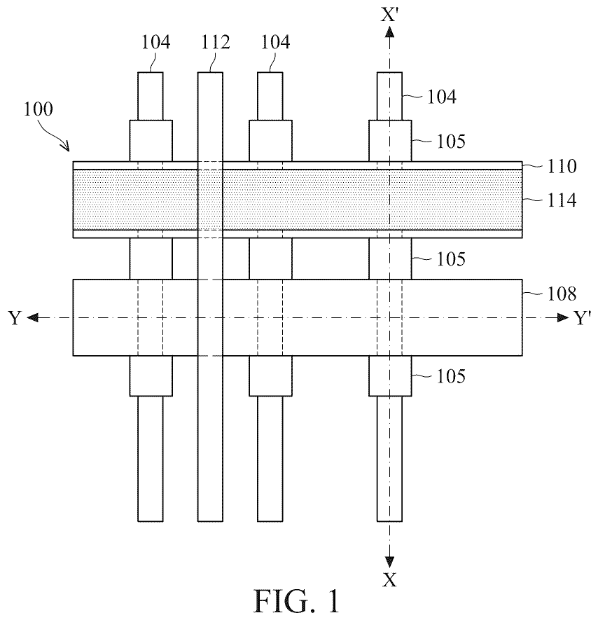

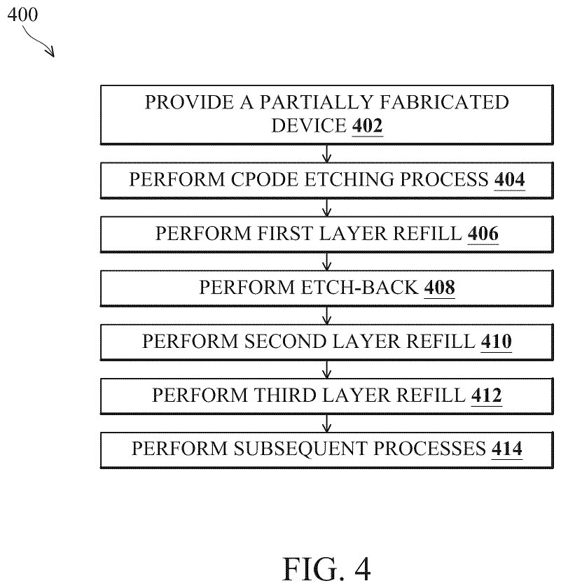

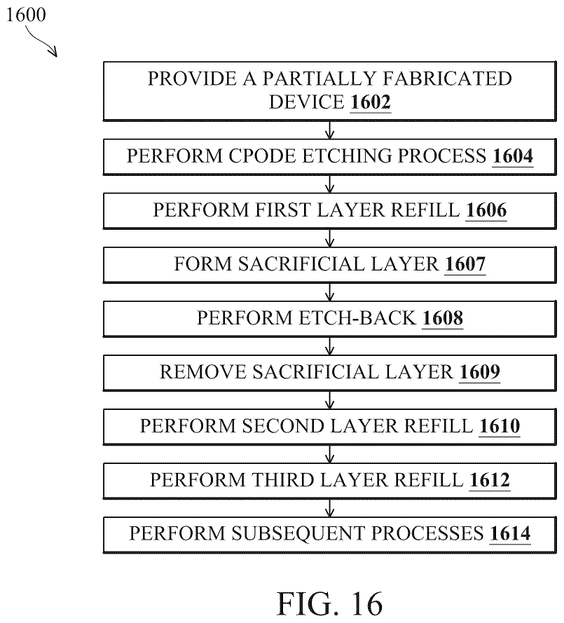

As previously noted, embodiments of the present disclosure may be applicable to various types of devices such as planar transistor devices, FinFET devices, GAA devices, forksheet devices, CFET devices, and the like. However, for clarity of discussion, aspects of the disclosed embodiments will be discussed with reference to an exemplary multi-gate device, such as shown and described below. By way of example, FIG. 1 provides a simplified top-down layout view of a multi-gate device 100. For purposes of this discussion, the multi-gate device 100 may include a FinFET device, a GAA transistor, or other type of multi-gate device. The multi-gate device 100 may include a plurality of fin elements 104 extending from a substrate, gate structures 108, 110 disposed over and around the fin elements 104, source/drain regions 105 (e.g., formed in, on, and/or surrounding the fins 104). In some cases, the gate structure 110 may include a dummy gate structure formed along an active edge. In an example, the multi-gate device 100 further includes a cut metal gate (CMG) region 112 that provides isolation between metal layers of adjacent structures (e.g., on either side of the CMG region 112). The multi-gate device 100 may further include a CPODE region 114, including a CPODE structure, disposed along the active edge and at least partially overlapping the dummy gate structure (the gate structure 110). The CPODE region 114, and the CPODE structure formed therein, may provide an isolation region (or dielectric plug) between neighboring active regions (e.g., such as regions on either side of the CPODE region 114). In at least some cases, the CMG region 112 may overlap the CPODE region 114, as shown. Channel regions of the multi-gate device 100, which may include a plurality of semiconductor channel layers (e.g., when the multi-gate device 100 includes a GAA transistor), are disposed within the fins 104, underlying the gate structure 108, along a plane substantially parallel to a plane defined by section XX′ of FIG. 1. In some embodiments, sidewall spacers may also be formed on sidewalls of the gate structures 108, 110. While some examples of the configuration of the CMG region 112 and the CPODE region 114 have been given, it will be understood that other configurations are possible, while remaining within the scope of the present disclosure. Various other features of the multi-gate device 100 are discussed in more detail below with reference to the methods of FIGS. 4 and 16.

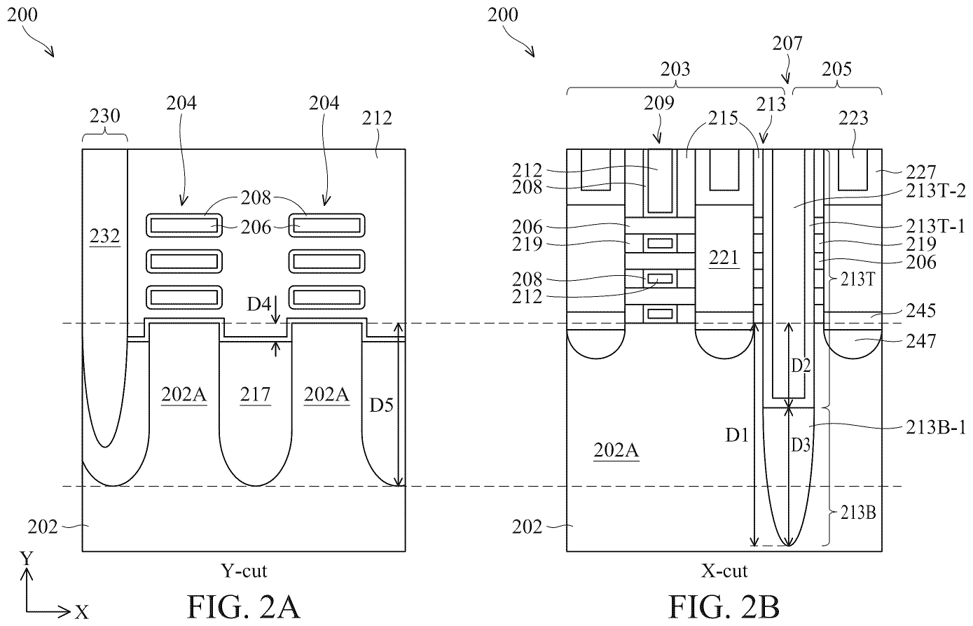

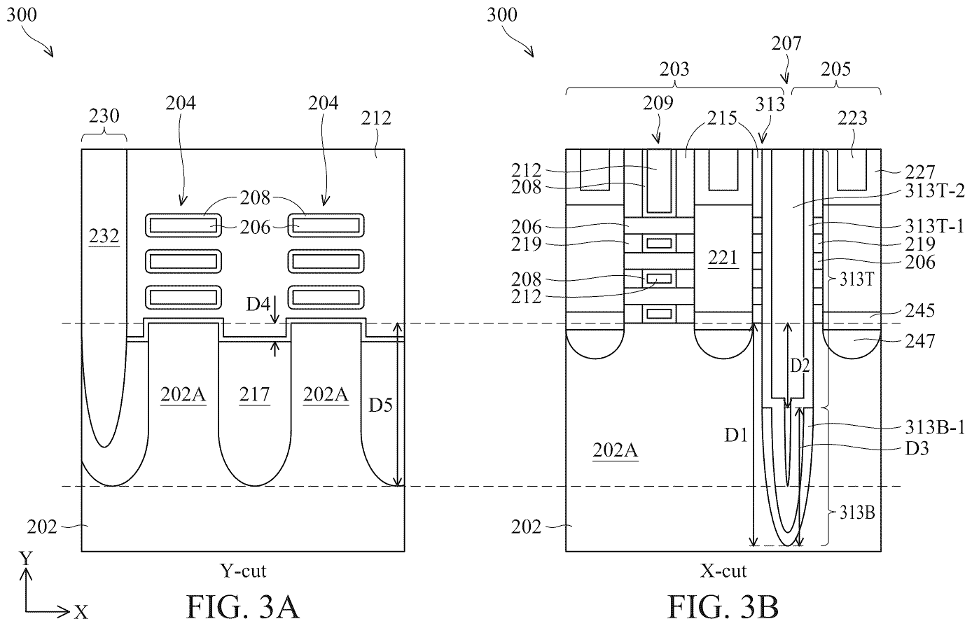

In accordance with embodiment of the present disclosure, the methods of FIGS. 4 and 16 may be implemented or modified in a variety of ways to fabricate semiconductor devices having CPODE structures with various configurations. Thus, before discussing the methods of FIGS. 4 and 16, and to provide context for discussion, reference is first made to FIGS. 2A/2B and 3A/3B, which provide illustrative embodiments of semiconductor devices 200 and 300, respectively, including different configurations of CPODE structures and fabricated in accordance with different embodiments of the disclosed methods (e.g., such as respective ones of the methods of FIGS. 4 and 16), as discussed in more detail below. FIGS. 2A and 3A provide cross-sectional views of embodiments of the semiconductor devices 200, 300 along a plane substantially parallel to a plane defined by section YY′ of FIG. 1. FIGS. 2B and 3B provide cross-sectional views of embodiments of the semiconductor devices 200, 300 along a plane substantially parallel to a plane defined by section XX′ of FIG. 1.

As shown in FIGS. 2B and 3B, the semiconductor devices 200, 300 include a first active region 203, a second active region 205, and an active edge 207 that is defined at a boundary of the first active region 203 and the second active region 205. In some embodiments, the first active region 203 includes a first GAA device 209, the second active region 205 includes a second GAA device (not shown), the active edge 207 of the semiconductor device 200 includes a CPODE structure 213, and the active edge 207 of the semiconductor device 300 includes a CPODE structure 313. Each of the CPODE structures 213, 313 provides an isolation region between the first active region 203 and the second active region 205 for the first and second semiconductor devices 200, 300, respectively. As described in more detail below, the CPODE structures 213, 313 may be formed by performing a dry etching process along the active edge 207, and through a dummy GAA structure disposed along the active edge 207, to form a cut region and filling the cut region with multiple dielectric layers of varying material composition stacked at least partially in a vertical direction. Additionally, and in some embodiments, the CPODE structures 213, 313 (as well as other CPODE structures discussed below), may include CPODE structures formed in CPODE regions such as the CPODE region 114, discussed above.

Each of the GAA devices formed in the first and second active regions 203, 205, and the CPODE structures 213, 313, are formed on a substrate 202 having fins 204. In some embodiments, the substrate 202 may be a semiconductor substrate such as a silicon substrate. The substrate 202 may include various layers, including conductive or insulating layers formed on a semiconductor substrate. The substrate 202 may include various doping configurations depending on design requirements as is known in the art. The substrate 202 may also include other semiconductors such as germanium, silicon carbide (SiC), silicon germanium (SiGe), or diamond. Alternatively, the substrate 202 may include a compound semiconductor and/or an alloy semiconductor. Further, the substrate 202 may optionally include an epi layer, may be strained for performance enhancement, may include a silicon-on-insulator (SOI) structure, and/or have other suitable enhancement features.

The fins 204 may include nanosheet channel layers 206. In some embodiments, the nanosheet channel layers 206 may include silicon (Si). However, in some embodiments, the nanosheet channel layers 206 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. By way of example, the nanosheet channel layers 206 may be epitaxially grown by a molecular beam epitaxy (MBE) process, a metalorganic chemical vapor deposition (MOCVD) process, and/or other suitable epitaxial growth processes.

With reference to the X and Y dimensions of the nanosheet channel layers 206 from an end-view of the nanosheet channel layers 206 (e.g., FIGS. 2A and 3A), the X-dimension may be equal to about 5-14 nm, and the Y-dimension may be equal to about 5-8 nm. In some cases, the X-dimension of the nanosheet channel layers 206 is substantially the same as the Y-dimension of the nanosheet channel layers 206. By way of example, the nanosheet channel layers 206 may be referred to as “nanosheets” when the X-dimension is greater than the Y-dimension. In some cases, a spacing (e.g., along the Y-direction) between adjacent nanosheet channel layers 206 is equal to about 4-8 nm.

In various embodiments, each of the fins 204 includes a substrate portion 202A formed from the substrate 202 and the nanosheet channel layers 206. It is noted that while the fins 204 are illustrated as including three (3) nanosheet channel layers 206, this is for illustrative purposes only and is not intended to be limiting beyond what is specifically recited in the claims. It can be appreciated that any number of nanosheet channel layers 206 can be formed, where for example, the number of nanosheet channel layers 206 depends on the desired number of channels regions for the GAA devices (e.g., devices formed in each of the first and second active regions 203, 205). In some embodiments, the number of nanosheet channel layers 206 is between 3 and 10.

Shallow trench isolation (STI) features 217 may also be formed interposing the fins 204. In some embodiments, the STI features 217 include SiO₂, silicon nitride, silicon oxynitride, fluorine-doped silicate glass (FSG), a low-K dielectric, combinations thereof, and/or other suitable materials known in the art. In various examples, the dielectric layer used to form the STI features 217 may be deposited by a CVD process, a subatmospheric CVD (SACVD) process, a flowable CVD process, an ALD process, a PVD process, and/or other suitable process.

In various examples, the devices formed in each of the first and second active regions 203, 205 further include a gate structure, which may include a high-K/metal gate stack. In some embodiments, the gate structure may form the gate associated with the multi-channels provided by the nanosheet channel layers 206 in the channel region of the respective GAA devices. The gate structure may include a gate dielectric 208 including an interfacial layer (IL) and a high-K gate dielectric layer formed over the interfacial layer. In some embodiments, the gate dielectric 208 has a total thickness of about 1-5 nm. High-K gate dielectrics, as used and described herein, include dielectric materials having a high dielectric constant, for example, greater than that of thermal silicon oxide (˜3.9).

In some embodiments, the interfacial layer of the gate dielectric 208 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. In some examples, the interfacial layer includes the chemical oxide layer, discussed above. The high-K gate dielectric layer of the gate dielectric 208 may include a high-K dielectric material such as hafnium oxide (HfO₂). Alternatively, the high-K gate dielectric layer may include other high-K dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-K gate dielectric layer may be formed by ALD, physical vapor deposition (PVD), CVD, oxidation, and/or other suitable methods.

The gate structure may further include a metal gate having a metal layer 212 formed over the gate dielectric 208. The metal layer 212 may include a metal, metal alloy, or metal silicide. The metal layer 212 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 212 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer 212 may be formed by ALD, PVD, CVD, e-beam evaporation, or other suitable process. Further, the metal layer 212 may be formed separately for N-type and P-type transistors which may use different metal layers. In addition, the metal layer 212 may provide an N-type or P-type work function, may serve as a transistor gate electrode, and in at least some embodiments, the metal layer 212 may include a polysilicon layer. As shown in FIGS. 2B and 3B, the gate structure includes portions that interpose each of the nanosheet channel layers 206 of the fins 204, where the nanosheet channel layers 206 each provide semiconductor channel layers for the devices formed in each of the first and second active regions 203, 205. Additionally, in some examples, another metal layer (e.g., such as a selectively-grown tungsten (W) layer) may be formed over the metal layer 212. In some cases, the selectively-grown W layer may include a fluorine-free W (FFW) layer. In various examples, the selectively-grown W layer may serve as an etch-stop layer and may also provide reduced contact resistance (e.g., to the metal layer 212).

In some embodiments, a spacer layer 215 may be formed on sidewalls of a top portion of the gate structure of each of the devices formed in each of the first and second active regions 203, 205, and the dummy GAA structure disposed along the active edge 207. The spacer layer 215 may be formed prior to formation of the high-K/metal gate stack of the gate structure, and prior to formation of the CPODE structures 213, 313. For example, in some cases, the spacer layer 215 may be formed on sidewalls of a previously formed dummy (sacrificial) gate stack that is removed and replaced by the high-K/metal gate stack, described above, as part of a replacement gate (gate-last) process. In some cases, the spacer layer 215 may have a thickness of about 2-10 nm. In various embodiments, the thickness of the spacer layer 215 may be selected to provide a desired sidewall profile following a CPODE dry etching process, as discussed in more detail below. In some examples, the spacer layer 215 may include a dielectric material such as silicon oxide, silicon nitride, silicon carbide, silicon oxynitride, SiCN, silicon oxycarbide, SiOCN, SiOHCN, a low-K material (e.g., with a dielectric constant ‘k’<7), and/or combinations thereof. In some embodiments, the spacer layer 215 includes multiple layers, such as main spacer layers, liner layers, and the like.

In various examples, each of the devices formed in each of the first and second active regions 203, 205, and the dummy GAA structure disposed along the active edge 207, further include inner spacers 219. The inner spacers 219 may be disposed between adjacent channels of the nanosheet channel layers 206, at lateral ends of the nanosheet channel layers 206, and in contact with portions of the gate structure that interpose each of the nanosheet channel layers 206 (or in contact with portions of the CPODE structures 213, 313 along the active edge 207, as shown). In some embodiments, the inner spacers 219 include amorphous silicon. In some examples, the inner spacers 219 may include silicon oxide, silicon nitride, silicon carbide, silicon oxynitride, SiCN, silicon oxycarbide, SiOCN, a low-K material (e.g., with a dielectric constant ‘k’<7), and/or combinations thereof. In various examples, the inner spacers 219 may extend beneath the spacer layer 215, described above, while abutting adjacent source/drain features, described below.

In some embodiments, source/drain features 221 are formed in source/drain regions adjacent to and on either side of the gate structure of each of the devices formed in each of the first and second active regions 203, 205 and over the substrate portion 202A. As a result, the CPODE structures 213, 313 along the active edge 207 are disposed between a first source/drain feature 221 of the first device in the first active region 203 and a second source/drain feature 221 of the second device in the second active region 205. As shown, the source/drain features 221 of the devices formed in each of the first and second active regions 203, 205 are in contact with the inner spacers 219 and nanosheet channel layers 206 of the respective devices formed in the first and second active regions 203, 205. Moreover, the source/drain features 221 (of the devices formed in each of the first and second active regions 203, 205) disposed on either side of the active edge 207 are separated from the CPODE structures 213, 313 by interposing portions of the inner spacers 219 and nanosheet channel layers 206 of the dummy GAA structure previously formed along the active edge 207.

In various examples, the source/drain features 221 include semiconductor epi layers such as Ge, Si, GaAs, AlGaAs, SiGe, GaAsP, SiP, or other suitable material, which may be formed by one or more epitaxial processes. In some embodiments, the source/drain features 221 may be in-situ doped during the epi process. For example, in some embodiments, epitaxially grown SiGe source/drain features may be doped with boron. In some cases, epitaxially grown Si source/drain features may be doped with carbon to form Si:C source/drain features, phosphorous to form Si:P source/drain features, or both carbon and phosphorous to form SiCP source/drain features. In some embodiments, the source/drain features 221 are not in-situ doped, and instead an implantation process is performed to dope the source/drain features 221. In some embodiments, formation of the source/drain features 221 may be performed in separate processing sequences for each of N-type and P-type source/drain features. Additionally, in some examples, an isolation layer 245 (e.g., such as a flexible bottom isolation layer) may optionally be formed beneath the source/drain features 221 and over an undoped layer 247. In an embodiment, the isolation layer 245 may be used to reduce leakage current and may include a dielectric layer such as SiN, SiON, SiOCN, SiOC, SiCN, SiO₂, AlOx, HfOx, and the like. The undoped layer 247, in some examples, may include an undoped Si layer or an undoped SiGe layer.

An inter-layer dielectric (ILD) layer 223 may also be formed over the devices 200, 300. In some embodiments, a contact etch stop layer (CESL) 227 is formed over the devices 200, 300 prior to forming the ILD layer 223. In some examples, the CESL 227 includes a silicon nitride layer, silicon oxide layer, a silicon oxynitride layer, and/or other materials known in the art. The CESL 227 may be formed by plasma-enhanced chemical vapor deposition (PECVD) process and/or other suitable deposition or oxidation processes. In some embodiments, the ILD layer 223 includes materials such as tetraethylorthosilicate (TEOS) oxide, un-doped silicate glass, or doped silicon oxide such as borophosphosilicate glass (BPSG), FSG, phosphosilicate glass (PSG), boron doped silicon glass (BSG), and/or other suitable dielectric materials. The ILD layer 223 may be deposited by a PECVD process or other suitable deposition technique. In some embodiments, a hard mask layer (e.g., such as SiN) may be formed over the ILD layer 223.

In some embodiments, a CMG process may be performed to isolate the metal layers 212 of adjacent structures. As part of the CMG process, a photolithography and etch process may be performed to etch the metal layer 212, the dielectric layer 208, and at least part of an underlying STI feature 217 in a CMG region 230 to form a trench that exposes the underlying STI feature 217. A refill process is performed to form a dielectric layer 232 in the trench that was formed in the CMG region 230. The dielectric layer 232 thus electrically isolates the metal layers 212 of adjacent structures. In some embodiments, the dielectric layer 232 includes a nitride layer such as SiN. Alternatively, in some cases, the dielectric layer 232 may include SiO₂, silicon oxynitride, FSG, a low-k dielectric, combinations thereof, and/or other suitable materials known in the art. In various examples, the dielectric layer 232 may be deposited by a CVD process, an SACVD process, a flowable CVD process, an ALD process, a PVD process, and/or other suitable process. Additionally, and in some embodiments, the CMG region 230 may include the CMG region 112, discussed above.

As shown, the CPODE structure 213 of the semiconductor device 200 includes a bottom portion 213B and a top portion 213T over the bottom portion 213B. In various embodiments, each of the bottom portion 213B and the top portion 213T may include one or more refill material layers. In the illustrated example of the semiconductor device 200, the bottom portion 213B includes a single refill material layer 213B-1, and the top portion 213T includes multiple refill material layers 213T-1 and 213T-2. In various embodiments, the refill material layer 213B-1 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the refill material layer 213B-1 may be described as including an SiO-like material. More generally, the refill material layer 213B-1 may include a fixed-charge free material for leakage current reduction. In some examples, the refill material layers 213T-1 and 213T-2 may also include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the refill material layers 213T-1 and 213T-2 may be described as including an SiN-like material. In various examples, the refill material layer 213B-1 may be different than the refill material layers 213T-1 and 213T-2. As part of the CPODE process, and in some embodiments, formation of the CPODE structure 213 may generally include a dry etching process along the active edge 207, and through a dummy GAA structure disposed along the active edge 207, to form a cut region (e.g., including a trench); filling the cut region (e.g., including filling the trench) with the refill material layer 213B-1 and performing an etch-back process; and depositing the refill material layers 213T-1 and 213T-2 in sequence. Additional CPODE process details used to form the CPODE structure 213 are discussed below with reference to the method of FIG. 4.

The CPODE structure 313 of the semiconductor device 300 similarly includes a bottom portion 313B and a top portion 313T over the bottom portion 313B. In various embodiments, each of the bottom portion 313B and the top portion 313T may include one or more refill material layers. In the illustrated example of the semiconductor device 300, the bottom portion 313B includes multiple refill material layers 313B-1, 313T-1, and 313T-2, and the top portion 313T includes multiple refill material layers 313T-1 and 313T-2. In various embodiments, each of the refill material layers 313B-1, 313T-1, and 313T-2 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the refill material layer 313B-1 may be described as including an SiO-like material. More generally, the refill material layer 313B-1 may include a fixed-charge free material. In some cases, the refill material layers 313T-1 and 313T-2 may be described as including an SiN-like material. In various examples, the refill material layer 313B-1 may be different than the refill material layers 313T-1 and 313T-2. As part of the CPODE process, and in some embodiments, formation of the CPODE structure 313 may generally include a dry etching process along the active edge 207, and through a dummy GAA structure disposed along the active edge 207, to form a cut region (e.g., including a trench); filling the cut region (e.g., including filling the trench) with the refill material layer 313B-1 and a sacrificial layer; performing an etch-back process; removing the sacrificial layer, and depositing the refill material layers 313T-1 and 313T-2 in sequence. In particular, and due to the use of the sacrificial layer, the refill material layers 313T-1 and 313T-2 are at least partially deposited within the bottom portion 313B, in this example. Additional CPODE process details used to form the CPODE structure 313 are discussed below with reference to the method of FIG. 16.

In some embodiments, the CPODE structures 213, 313 have a total depth ‘D1’ measured from a plane level with a top surface of a substrate mesa (e.g., a top surface of the substrate portion 202A) to a plane level with a bottom of the CPODE structures 213, 313. In some examples, the depth ‘D1’ may be in a range of between about 80-250 nm. The total depth ‘D1’ may be composed of a depth ‘D2’ and a depth ‘D3’, as shown. The depth ‘D2’ is measured from the plane level with the top surface of a substrate mesa to a plane level with a bottom of the top portions 213T, 313T of respective ones of the CPODE structures 213, 313. It is noted that the plane level with the bottom of the top portions 213T, 313T is coplanar with a plane level with a top of the bottom portion 213B, 313B of respective ones of the CPODE structures 213, 313. The depth ‘D3’ is measured from the top of the bottom portions 213B, 313B (or equivalently from the bottom of the top portions 213T, 313T) to the plane level with the bottom of the CPODE structures 213, 313 (or equivalently a plane level with the bottom of the bottom portions 213B, 313B).

As also shown, the STI features 217 have a depth ‘D5’ measured from the plane level with the top surface of a substrate mesa to a plane level with a bottom of the STI features 217. In some examples, the depth ‘D5’ may be in a range of between about 50-150 nm. Further, a depth ‘D4’ may be defined as the distance from the plane level with the top surface of a substrate mesa to a plane level with a top of the STI features 217. In some embodiments, the depth ‘D4’ may be in a range of between about 3-30 nm. In various examples, the depth ‘D2’ may be greater than the depth ‘D4’ and less than the depth ‘D5’. As a result, the bottom portions 213B, 313B of the CPODE structures 213, 313 are buried within the substrate 202 below the plane level with a top of the STI features 217 (e.g., to prevent exposure to post processing), and the top of the bottom portions 213B, 313B of the CPODE structures 213, 313 are higher than (closer to the top of the substrate 202) the bottom of the STI features 217. While the total depth ‘D1’ of the CPODE structures 213, 313 is illustrated as being greater than the depth ‘D5’ of the STI features 217, in at least some embodiments, the total depth ‘D1’ may be less than the depth ‘D5’.

The illustrative embodiments of the semiconductor devices 200, 300, discussed above and including the respective CPODE structures 213, 313, may be fabricated in accordance with different embodiments of the disclosed methods, discussed below (e.g., such as respective ones of the methods of FIGS. 4 and 16). Moreover, variations of the disclosed methods may be provided to fabricate semiconductor devices with CPODE structures of various other configurations, as also discussed below. It is also noted that aspects of the semiconductor devices 200, 300, discussed above, may equally apply to the various embodiments of the disclosed methods, devices, and CPODE structures, discussed below. Thus, reference numerals, terminology, or other descriptors used in the discussion of the semiconductor devices 200, 300 may also be used in the discussion that follows to indicate like features or aspects of the various embodiments. In addition, while the examples disclosed herein are discussed with reference to a CPODE structure having two portions (e.g., a top portion and a bottom portion), other embodiments are possible. For instance, in some cases, the CPODE structure may have three or more portions, where each portion includes one or more refill layers composed of an SiO-like material, an SiN-like material, another material as described herein, or combinations thereof.

Referring now to FIG. 4, illustrated therein is a method 400 of fabrication of a semiconductor device 500 including a CPODE structure, in accordance with various embodiments. The method 400 is discussed below with reference to a semiconductor device including a GAA device having a channel region that may be referred to as a nanosheet and which may include various geometries (e.g., cylindrical, bar-shaped) and dimensions. However, it will be understood that aspects of the method 400, including the disclosed CPODE structure, may be equally applied to other types of devices, as discussed above, without departing from the scope of the present disclosure. In some embodiments, the method 400 may be used to fabricate the multi-gate device 100 (described above with reference to FIG. 1) or the semiconductor device 200 (described above with reference to FIGS. 2A/2B). Thus, one or more aspects discussed above with reference to the multi-gate device 100 and/or the semiconductor device 200 may also apply to the method 400. It is understood that the method 400 includes steps having features of a complementary metal-oxide-semiconductor (CMOS) technology process flow and thus, are only described briefly herein. Also, additional steps may be performed before, after, and/or during the method 400.

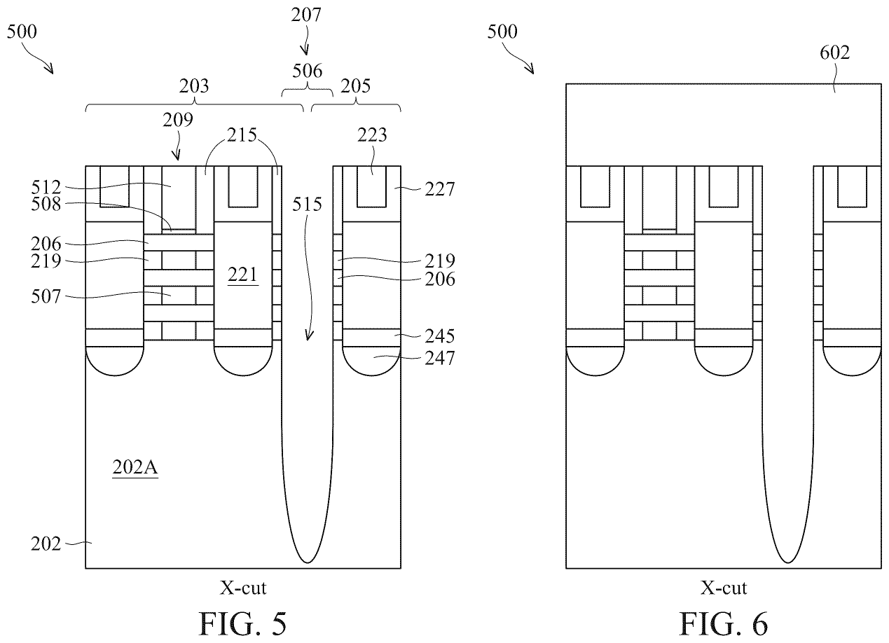

The method 400 is described below with reference to FIGS. 5-8, which illustrate the semiconductor device 500 at various stages of fabrication according to the method 400. FIGS. 5-8 provide cross-sectional views of an embodiment of the semiconductor device 500 along a plane substantially parallel to a plane defined by section XX′ of FIG. 1. The method 400 begins at block 402 where a partially fabricated multi-gate device is provided. With reference to FIGS. 5 and 2B, in an embodiment of block 402, the initially provided, partially fabricated semiconductor device 500 may include the semiconductor device 200 at an earlier stage of processing (e.g., prior to performing a replacement gate process and prior to the CMG process). The semiconductor device 500 thus includes the first active region 203, the second active region 205, and the active edge 207, as discussed above. The first active region 203 includes the first GAA device 209, the second active region 205 includes the second GAA device (not shown), and the active edge 207 initially includes a dummy GAA structure where a CPODE structure will subsequently be formed. The semiconductor device 500 further includes the nanosheet channel layers 206, the inner spacers 219, the spacer layer 215, the source/drain features 221, the ILD layer 223, the CESL 227, the isolation layer 245, and the undoped layer 247, as described above. The semiconductor device 500, provided prior to the replacement gate process, includes a dummy gate structure and sacrificial layers 507 (e.g., such as sacrificial SiGe layer) interposing adjacent ones of the nanosheet channel layers 206 to provide a semiconductor layer stack. In some embodiments, the dummy gate structure includes a dummy gate dielectric 508 and a dummy gate electrode 512. The dummy gate dielectric 508 includes a dielectric material, such as silicon oxide, a high-K dielectric material, other suitable dielectric material, or a combination thereof. The dummy gate electrode 512 includes a suitable dummy gate material, such as polysilicon.

The method 400 proceeds to block 404 where a CPODE etching process is performed. Still with reference to FIG. 5, in an embodiment of block 404, a CPODE etching process is performed to form a trench 515 in a CPODE region 506 of the semiconductor device 500. The CPODE region 506 may include the active edge 207 and the dummy GAA structure initially formed along the active edge 207. In some cases, the CPODE etching process includes a dry etching process. In some embodiments, the CPODE etching process removes, from the CPODE region 506, the dummy gate structure (including the dummy gate electrode 512 and the dummy gate dielectric 508), and portions of the nanosheet channel layers 206, the sacrificial layers 507, and portions of the inner spacers 219 that are not protected by (disposed directly below) the spacer layer 215. As a result, the trench 515 may include at least some portions of the nanosheet channel layers 206 and the inner spacers 219 along sidewalls (in a sidewall region) of the trench 515 and disposed between the trench 515 and the adjacent source/drain features 221. It is noted that the CPODE etching process may also remove at least some of the substrate portion 202A of the dummy GAA structure initially formed along the active edge 207 (e.g., within the CPODE region 506). In various embodiments, a thickness of the spacer layer 215 may be selected to provide a desired sidewall profile following the CPODE etching process, for example, depending on various device and/or process parameters and specifications.

The method 400 proceeds to block 406 where a first refill process is performed. With reference to FIGS. 5 and 6, in an embodiment of block 406, a first refill process is used to form a first refill layer 602 over the device 500 and within the trench 515 formed by the CPODE etching process. In some embodiments, the first refill layer 602 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the first refill layer 602 may be described as including an SiO-like material. More generally, the first refill layer 602 may include a fixed-charge free material that effectively reduces leakage current between the substrate 202 and the first refill layer 602. In various examples, the first refill layer 602 may be deposited by a CVD process, an SACVD process, a flowable CVD process, an ALD process, a PVD process, and/or other suitable process. In some cases, after forming the first refill layer 602, a CMP process may be performed to remove excess material and planarize a top surface of the device 500.

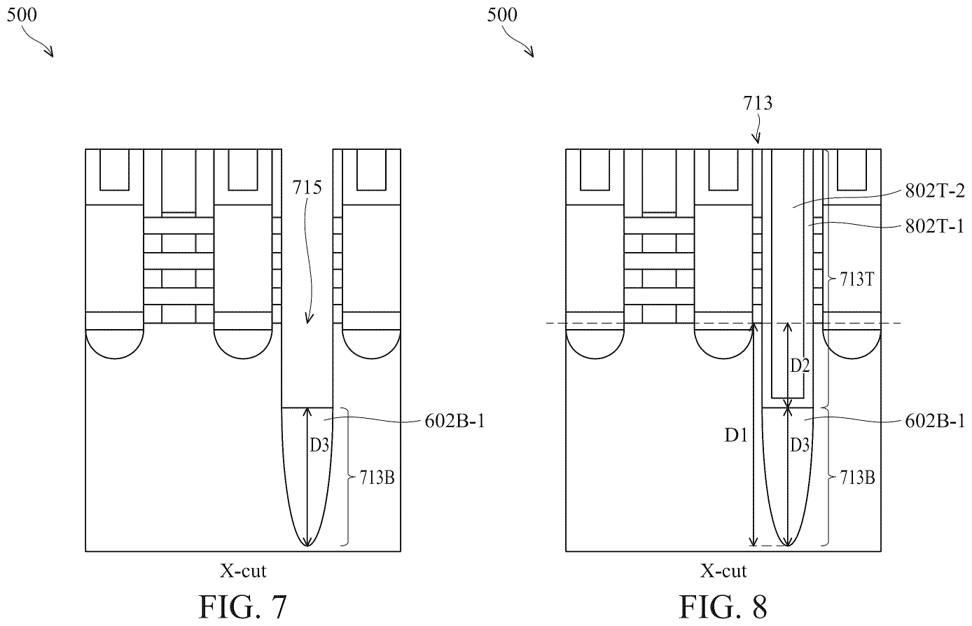

The method 400 proceeds to block 408 where an etch-back process is performed. With reference to FIGS. 6 and 7, after performing the CMP process and in an embodiment of block 408, an etch-back process is performed to etch back the first refill layer 602, thus forming an etched-back first refill layer 602B-1 and a trench 715 in the CPODE region 506 of the semiconductor device 500. In some embodiments, the etch-back process includes a wet etching process, a dry etching process, or a combination thereof. Like the trench 515, the trench 715 may include at least some portions of the nanosheet channel layers 206 and the inner spacers 219 along sidewalls (in a sidewall region) of the trench 715 and disposed between the trench 715 and the adjacent source/drain features 221. In particular, the etch-back process of block 408 serves to define a bottom portion 713B of a CPODE structure that includes the etched-back first refill layer 602B-1 (similar to the bottom portion 213B that includes the refill material layer 213B-1, discussed above). Further, the etch-back process of block 408 serves to define the depth ‘D3’ measured from the top of the bottom portion 713B to the plane level with the bottom of the bottom portion 713B.

The method 400 proceeds to block 410 where a second refill process is performed. With reference to FIGS. 7 and 8, in an embodiment of block 410, a second refill process is used to form a second refill layer 802T-1 over the device 500 and along sidewalls and bottom surfaces of the trench 715 formed by the etch-back process of block 408. Thus, in some cases, the second refill layer 802T-1 may be described as being conformally deposited within the trench 715. In some embodiments, the second refill layer 802T-1 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the second refill layer 802T-1 may be described as including an SiN-like material. In various examples, the second refill layer 802T-1 may be different than the first refill layer 602B-1. In various examples, the second refill layer 802T-1 may be deposited by a CVD process, an SACVD process, a flowable CVD process, an ALD process, a PVD process, and/or other suitable process.

The method 400 proceeds to block 412 where a third refill process is performed. Still with reference to FIGS. 7 and 8, in an embodiment of block 412, a third refill process is used to form a third refill layer 802T-2 over the device 500, within the trench 715, and over the second refill layer 802T-1 previously deposited at block 410. In some embodiments, the third refill layer 802T-2 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the third refill layer 802T-2 may also be described as including an SiN-like material. In various examples, the third refill layer 802T-2 may be different than the second refill layer 802T-1 and the first refill layer 602B-1. In various examples, the third refill layer 802T-2 may be deposited by a CVD process, an SACVD process, a flowable CVD process, an ALD process, a PVD process, and/or other suitable process. After formation of the third refill layer 802T-2, a CMP process may be performed to remove excess material and planarize a top surface of the device 500. Also, after formation of the third refill layer 802T-2, a top portion 713T of a CPODE structure is defined, the top portion 713T including the second refill layer 802T-1 and the third refill layer 802T-2 (similar to the top portion 213T that includes the refill material layers 213T-1 and 213T-2, discussed above). More specifically, after formation of the third refill layer 802T-2, a CPODE structure 713 (including the bottom portion 713B and the top portion 713T) is defined, where the CPODE structure 713 is substantially the same as the CPODE structure 213, discussed above. It is also noted that the etch-back process of block 408 further serves to define the depth ‘D2’ measured from the plane level with the top surface of a substrate mesa to a plane level with a bottom of the top portion 713T. The total depth ‘D1’ of the CPODE structure 713 is thus the sum of the depth ‘D2’ and the depth ‘D3’.

The method 400 proceeds to block 414 where subsequent processing is performed. For example, in some embodiments and after forming the CPODE structure 713, a channel release process and replacement gate process may be performed to remove the dummy gate structure (including the dummy gate dielectric 508 and the dummy gate electrode 512) and the sacrificial layers 507, and replace them with a high-K/metal gate stack, such as described with reference to the semiconductor device 200. In some cases, after the channel release process and the replacement gate process, a CMG process may be performed to form a dielectric layer in a CMG region that isolates metal layers of adjacent structures, as also described above with reference to the semiconductor device 200. Thus, in some embodiments and after the block 414, the semiconductor device 500 may be substantially the same as the semiconductor device 200, discussed above.

While the method 400 is described as first forming the CPODE structure 713, then performing the channel release process and the replacement gate process, and then performing the CMG process, other embodiments are possible and within the scope of the present disclosure. For example, in some cases, the method 400 may first perform the channel release process and the replacement gate process, followed by the CMG process, and then the CPODE structure 713 may be formed. In other examples, the method 400 may first perform the channel release process and the replacement gate process, followed by formation of the CPODE structure 713, and then the CMG process may be performed. In still other embodiments, the method 400 may first perform the CMG process, followed by formation of the CPODE structure 713, and then the channel release process and the replacement gate process may be performed. In some cases, the method 400 may first perform the CMG process, followed by performing the channel release process and the replacement gate process, and then the CPODE structure 713 may be formed.

Generally, the semiconductor device 500 may undergo further processing to form various features and regions known in the art. For example, subsequent processing may form contact openings, contact metal, as well as various contacts/vias/lines and multilayer interconnect features (e.g., metal layers and interlayer dielectrics) on the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 400, and some process steps described above may be replaced or eliminated in accordance with various embodiments of the method 400. Further, while the method 400 has been shown and described as including the device 500 having a GAA device, it will be understood that other device configurations are possible. In some embodiments, the method 400 may be used to fabricate various types of devices such as planar transistor devices, FinFET devices, forksheet devices, CFET devices, and the like.

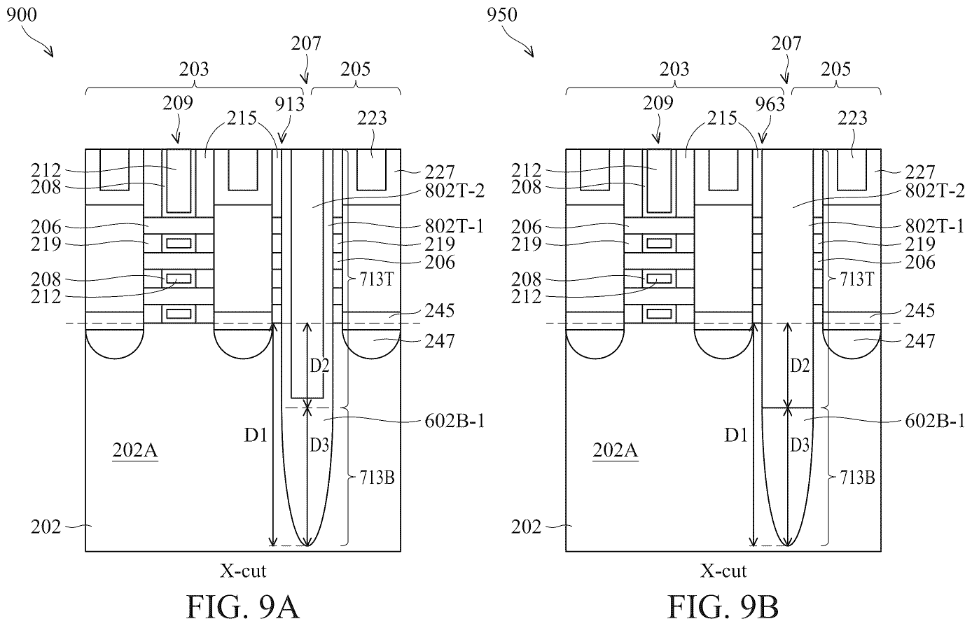

As previously noted, variations of the disclosed methods may be provided to fabricate semiconductor devices with CPODE structures of various other configurations. With respect to the method 400, the process steps of the method may be modified to fabricate devices with a number of different CPODE structure configurations. For instance, reference is made to FIGS. 9A, 9B, and 10-15, which illustrate embodiments of semiconductor devices fabricated in accordance with the method 400 and having CPODE structures of varying configurations. As shown, the examples of FIGS. 9A, 9B, and 10-15 include devices after the subsequent processing of block 414 (e.g., after the channel release process and the replacement gate process, and including a high-K/metal gate stack).

With reference to FIG. 9A, illustrated therein is a semiconductor device 900, similar to the semiconductor devices 200, 500 fabricated using the method 400. However, the semiconductor device 900 includes a different CPODE structure 913. In particular, in the CPODE structure 913, the second refill layer 802T-1 is the same as the first refill layer 602B-1. In contrast, in the CPODE structure 713 of the semiconductor device 500, the second refill layer 802T-1 is different than the first refill layer 602B-1.

With reference to FIG. 9B, illustrated therein is a semiconductor device 950, similar to the semiconductor devices 200, 500 fabricated using the method 400. However, the semiconductor device 950 includes a different CPODE structure 963. In particular, in the CPODE structure 963, the second refill layer 802T-1 and the third refill layer 802T-2 may be the same (e.g., composed of the same material). As a result, the bottom portion 713B of the CPODE structure 963 includes one dielectric layer (the first refill layer 602B-1) and the top portion 713T of the CPODE structure 963 effectively includes one dielectric layer (the second and third refill layers 802T-1, 802T-2 composed of the same material). Also, in at least some cases, instead of separately depositing both the second refill layer 802T-1 and the third refill layer 802T-2, blocks 410 and 412 may be combined into a single deposition of the refill material used to form the top portion 713T of the CPODE structure 963.

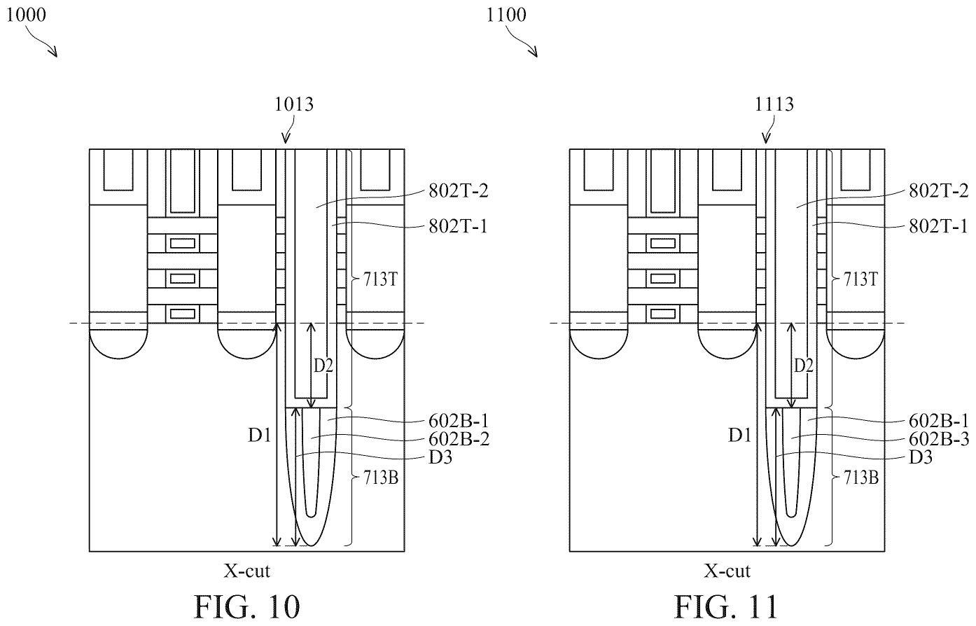

With reference to FIG. 10, illustrated therein is a semiconductor device 1000, similar to the semiconductor devices 200, 500 fabricated using the method 400. However, the semiconductor device 1000 includes a different CPODE structure 1013. In particular, in the CPODE structure 1013, the bottom portion 713B includes multiple refill layers. As shown, the bottom portion 713B may include the first refill layer 602B-1 and another refill layer 602B-2. In some embodiments, instead of completely filling the trench 515 with the first refill layer at block 406 of the method 400, the first refill layer 602B-1 may be conformally deposited within the trench 515 (e.g., along sidewalls and a bottom surface of the trench 515). Thereafter, the additional bottom refill layer 602B-2 may be deposited within the trench 515 and over the first refill layer 602B-1, thereby filling the trench 515. In some embodiments, the additional bottom refill layer 602B-2 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the additional bottom refill layer 602B-2 may be described as including an SiO-like material. In various examples, the additional bottom refill layer 602B-2 may be different than the first refill layer 602B-1. In some embodiments, the additional bottom refill layer 602B-2 may also be different than the third refill layer 802T-2 and the second refill layer 802T-1 of the top portion 713T. In various examples, the additional bottom refill layer 602B-2 may be deposited by a CVD process, an SACVD process, a flowable CVD process, an ALD process, a PVD process, and/or other suitable process. After forming the additional bottom refill layer 602B-2, the method 400 proceeds to block 408 where the etch-back process is performed, as described above.

With reference to FIG. 11, illustrated therein is a semiconductor device 1100, similar to the semiconductor devices 200, 500 fabricated using the method 400. However, the semiconductor device 1100 includes a different CPODE structure 1113. In particular, in the CPODE structure 1113, the bottom portion 713B includes a refill layer and an air gap. As shown, the bottom portion 713B may include the first refill layer 602B-1 and an air gap 602B-3. Like the embodiment of FIG. 10, instead of completely filling the trench 515 with the first refill layer at block 406 of the method 400, the first refill layer 602B-1 may be conformally deposited within the trench 515 (e.g., along sidewalls and a bottom surface of the trench 515). Thereafter, and in contrast to the embodiment of FIG. 10, instead of depositing another bottom refill layer to completely fill the trench 515, the method 400 proceeds to block 408 where the etch-back process is performed, as described above. In various embodiments, inclusion of the air gap 602B-3 reduces parasitic capacitance and may enhance performance of the device 1100. It is also noted that subsequent deposition of the second refill layer 802T-1 and the third refill layer 802T-2 may be tuned (e.g., by appropriate selection of the materials and/or deposition processes used for the second refill layer 802T-1 and the third refill layer 802T-2) so that the second refill layer 802T-1 and the third refill layer 802T-2 are not deposited within the air gap 602B-3. Stated another way, the air gap 602B-3 may be substantially free of the second refill layer 802T-1 and the third refill layer 802T-2.

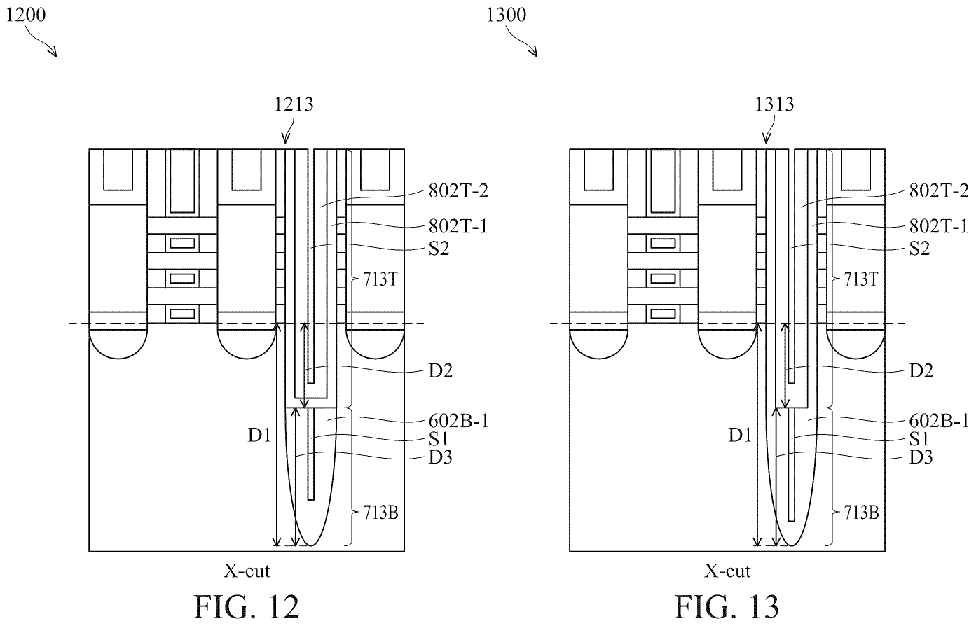

With reference to FIG. 12, illustrated therein is a semiconductor device 1200, similar to the semiconductor devices 200, 500 fabricated using the method 400. However, the semiconductor device 1200 includes a different CPODE structure 1213. In particular, in the CPODE structure 1213, the material selected for the first refill layer 602B-1 and the third refill layer 802T-2 includes poor gap-fill materials. The poor gap-fill materials may be intentionally selected so as to form a seam S1 within the bottom portion 713B and a seam S2 within the top portion 713T. In some examples, the poor gap-fill material may be selected for only one of the first refill layer 602B-1 and the third refill layer 802T-2, such that only one of the seams S1 or S2 may be formed. By way of illustration, the poor gap-fill material used for the first refill layer 602B-1 may be deposited as part of the first layer refill process of block 406 of the method 400, and the poor gap-fill material used for the third refill layer 802T-2 may be deposited as part of the third layer refill process of block 412 of the method 400. In some embodiments, inclusion of the seams S1, S2 may reduce parasitic capacitance and enhance performance of the device 1200.

With reference to FIG. 13, illustrated therein is a semiconductor device 1300, similar to the semiconductor devices 200, 500 fabricated using the method 400. However, the semiconductor device 1300 includes a different CPODE structure 1313. In an example, the CPODE structure 1313 may be a combination of aspects of the embodiments illustrated in FIGS. 9A and 12. For example, in the CPODE structure 1313, the second refill layer 802T-1 is the same as the first refill layer 602B-1 (e.g., like the embodiment of FIG. 9A). In addition, the material selected for the first refill layer 602B-1 and the third refill layer 802T-2 includes poor gap-fill materials, resulting in the seam S1 within the bottom portion 713B and the seam S2 within the top portion 713T (e.g., like the embodiment of FIG. 12). As noted above, and in some examples, the poor gap-fill material may be selected for only one of the first refill layer 602B-1 and the third refill layer 802T-2, such that only one of the seams S1 or S2 may be formed.

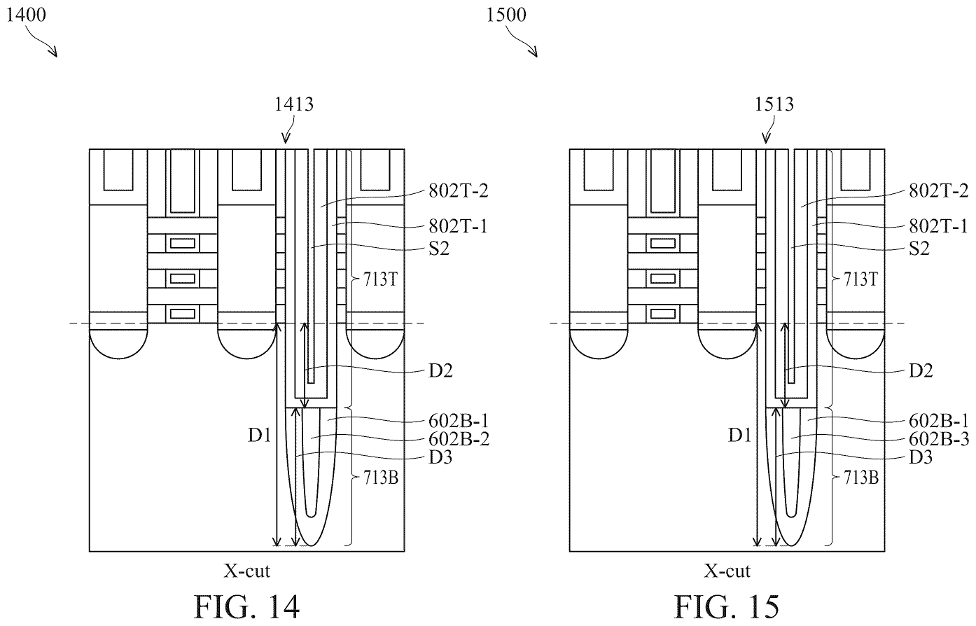

With reference to FIG. 14, illustrated therein is a semiconductor device 1400, similar to the semiconductor devices 200, 500 fabricated using the method 400. However, the semiconductor device 1400 includes a different CPODE structure 1413. In an example, the CPODE structure 1413 may be a combination of aspects of the embodiments illustrated in FIGS. 10 and 12. For example, in the CPODE structure 1413, the bottom portion 713B may include the first refill layer 602B-1 and another refill layer 602B-2 (e.g., like the embodiment of FIG. 10). In addition, the material selected for the third refill layer 802T-2 includes a poor gap-fill material, resulting in the seam S2 within the top portion 713T (e.g., like the embodiment of FIG. 12).

With reference to FIG. 15, illustrated therein is a semiconductor device 1500, similar to the semiconductor devices 200, 500 fabricated using the method 400. However, the semiconductor device 1500 includes a different CPODE structure 1513. In an example, the CPODE structure 1513 may be a combination of aspects of the embodiments illustrated in FIGS. 11 and 12. For example, in the CPODE structure 1513, the bottom portion 713B may include the first refill layer 602B-1 and the air gap 602B-3 (e.g., like the embodiment of FIG. 11). In addition, the material selected for the third refill layer 802T-2 includes a poor gap-fill material, resulting in the seam S2 within the top portion 713T (e.g., like the embodiment of FIG. 12).

Referring now to FIG. 16, illustrated therein is a method 1600 of fabrication of a semiconductor device 1700 including a CPODE structure, in accordance with various embodiments. The method 1600 is discussed below with reference to a semiconductor device including a GAA device having a channel region that may be referred to as a nanosheet and which may include various geometries (e.g., cylindrical, bar-shaped) and dimensions. However, it will be understood that aspects of the method 1600, including the disclosed CPODE structure, may be equally applied to other types of devices, as discussed above, without departing from the scope of the present disclosure. In some embodiments, the method 1600 may be used to fabricate the multi-gate device 100 (described above with reference to FIG. 1) or the semiconductor device 300 (described above with reference to FIGS. 3A/3B). Thus, one or more aspects discussed above with reference to the multi-gate device 100 and/or the semiconductor device 300 may also apply to the method 1600. In addition, the method 1600 is similar in some respects to the method 400 of FIG. 4. Therefore, one or more aspects discussed above with reference to the method 400 may also apply to the method 1600. It is understood that the method 1600 includes steps having features of a CMOS technology process flow and thus, are only described briefly herein. Also, additional steps may be performed before, after, and/or during the method 1600.

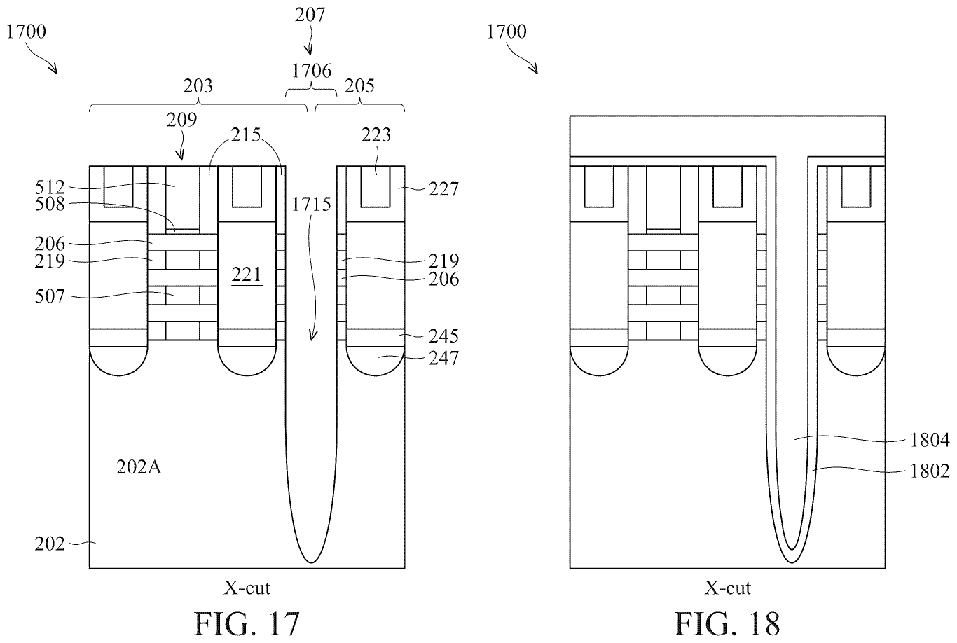

The method 1600 is described below with reference to FIGS. 17-21, which illustrate the semiconductor device 1700 at various stages of fabrication according to the method 1600. FIGS. 17-21 provide cross-sectional views of an embodiment of the semiconductor device 1700 along a plane substantially parallel to a plane defined by section XX′ of FIG. 1. The method 1600 begins at block 1602 where a partially fabricated multi-gate device is provided. In some embodiments, the partially fabricated multi-gate device provided at block 1602 may be similar to that provided at block 402 of FIG. 4. With reference to FIGS. 17 and 3B, in an embodiment of block 1602, the initially provided, partially fabricated semiconductor device 1700 may include the semiconductor device 300 at an earlier stage of processing (e.g., prior to performing a replacement gate process and prior to the CMG process). The semiconductor device 1700 thus includes the first active region 203, the second active region 205, and the active edge 207, as discussed above. The first active region 203 includes the first GAA device 209, the second active region 205 includes the second GAA device (not shown), and the active edge 207 initially includes a dummy GAA structure where a CPODE structure will subsequently be formed. The semiconductor device 1700 further includes the nanosheet channel layers 206, the inner spacers 219, the spacer layer 215, the source/drain features 221, the ILD layer 223, the CESL 227, the isolation layer 245, and the undoped layer 247, as described above. The semiconductor device 1700, provided prior to the replacement gate process, includes a dummy gate structure and sacrificial layers 507 (e.g., such as sacrificial SiGe layer) interposing adjacent ones of the nanosheet channel layers 206. In some embodiments, the dummy gate structure includes a dummy gate dielectric 508 and a dummy gate electrode 512. The dummy gate dielectric 508 includes a dielectric material, such as silicon oxide, a high-K dielectric material, other suitable dielectric material, or a combination thereof. The dummy gate electrode 512 includes a suitable dummy gate material, such as polysilicon.

The method 1600 proceeds to block 1604 where a CPODE etching process is performed. Still with reference to FIG. 17, in an embodiment of block 1604, a CPODE etching process is performed to form a trench 1715 in a CPODE region 1706 of the semiconductor device 1700. The CPODE region 1706 may include the active edge 207 and the dummy GAA structure initially formed along the active edge 207. In some cases, the CPODE etching process includes a dry etching process. In some embodiments, the CPODE etching process removes, from the CPODE region 1706, the dummy gate structure (including the dummy gate electrode 512 and the dummy gate dielectric 508), and portions of the nanosheet channel layers 206, the sacrificial layers 507, and portions of the inner spacers 219 that are not protected by (disposed directly below) the spacer layer 215. As a result, the trench 1715 may include at least some portions of the nanosheet channel layers 206 and the inner spacers 219 along sidewalls (in a sidewall region) of the trench 1715 and disposed between the trench 1715 and the adjacent source/drain features 221. It is noted that the CPODE etching process may also remove at least some of the substrate portion 202A of the dummy GAA structure initially formed along the active edge 207 (e.g., within the CPODE region 1706). In various embodiments, a thickness of the spacer layer 215 may be selected to provide a desired sidewall profile following the CPODE etching process, for example, depending on various device and/or process parameters and specifications.

The method 1600 proceeds to block 1606 where a first refill process is performed. With reference to FIGS. 17 and 18, in an embodiment of block 1606, a first refill process is used to form a first refill layer 1802 over the device 1700 and conformally within the trench 1715 (e.g., along sidewalls and a bottom surface of the trench 1715) formed by the CPODE etching process. In some embodiments, the first refill layer 1802 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the first refill layer 1802 may be described as including an SiO-like material. More generally, the first refill layer 1802 may include a fixed-charge free material that effectively reduces leakage current between the substrate 202 and the first refill layer 1802. In various examples, the first refill layer 1802 may be deposited by a CVD process, an SACVD process, a flowable CVD process, an ALD process, a PVD process, and/or other suitable process.

The method 1600 proceeds to block 1607 where a sacrificial layer is formed. Still with reference to FIGS. 17 and 18, in an embodiment of block 1607, a sacrificial layer 1804 may be deposited within the trench 1715 and over the first refill layer 1802, thereby filling the trench 1715. In some embodiments, the sacrificial layer 1804 includes a bottom-antireflective coating (BARC) layer. In some cases, the sacrificial layer 1804 may alternatively include other materials such as resins, other polymers, or resists. In various examples, the sacrificial layer 1804 may be deposited by a CVD process, an SACVD process, a flowable CVD process, an ALD process, and/or other suitable process. In some cases, after forming the first refill layer 1802 and the sacrificial layer 1804, a CMP process may be performed to remove excess material and planarize a top surface of the device 1700.

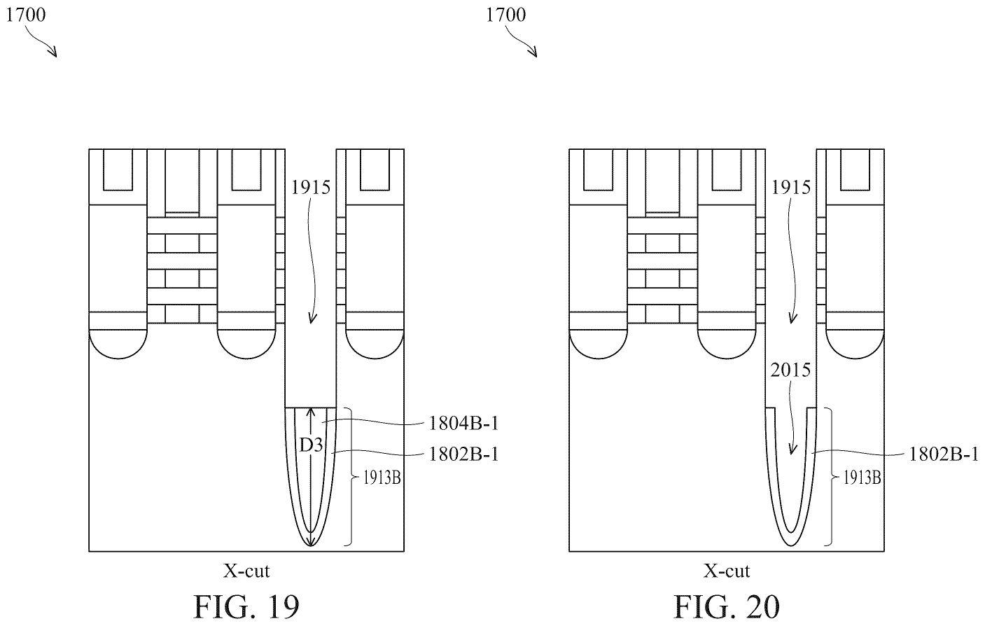

The method 1600 proceeds to block 1608 where an etch-back process is performed. With reference to FIGS. 18 and 19, after performing the CMP process and in an embodiment of block 1608, an etch-back process is performed to etch back the first refill layer 1802 and the sacrificial layer 1804, thus forming an etched-back first refill layer 1802B-1, an etched-back sacrificial layer 1804B-1, and a trench 1915 in the CPODE region 1706 of the semiconductor device 1700. In some embodiments, the etch-back process includes a wet etching process, a dry etching process, or a combination thereof. Like the trench 1715, the trench 1915 may include at least some portions of the nanosheet channel layers 206 and the inner spacers 219 along sidewalls (in a sidewall region) of the trench 1915 and disposed between the trench 1915 and the adjacent source/drain features 221. In particular, the etch-back process of block 1608 serves to at least partially define a bottom portion 1913B of a CPODE structure that includes the etched-back first refill layer 1802B-1 and the etched-back sacrificial layer 1804B-1. Further, the etch-back process of block 1608 serves to define the depth ‘D3’ measured from the top of the bottom portion 1913B to the plane level with the bottom of the bottom portion 1913B.

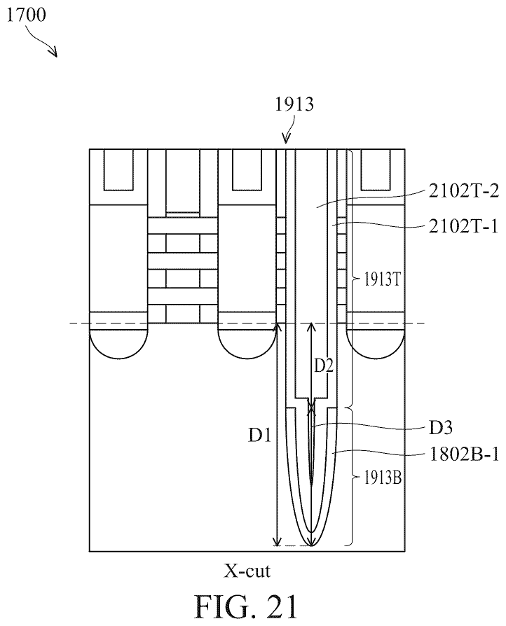

The method 1600 proceeds to block 1609 where the sacrificial layer is removed. With reference to FIGS. 19 and 20, in an embodiment of block 1609, the etched-back sacrificial layer 1804B-1 may be removed to form a trench 2015 below the trench 1915, the trenches 1915, 2015 forming a contiguous trench. As shown, the trench 2015 may include the etched-back first refill layer 1802B-1 along sidewalls (in a sidewall region) of the trench 2015. In various embodiments, the etched-back sacrificial layer 1804B-1 may be removed using a wet etch, a dry etch, or a combination thereof.

The method 1600 proceeds to block 1610 where a second refill process is performed. With reference to FIGS. 20 and 21, in an embodiment of block 1610, a second refill process is used to form a second refill layer 2102T-1 over the device 1700, along sidewalls of the trench 1915, and along sidewalls and bottom surfaces of the trench 2015 (including over the etched-back first refill layer 1802B-1 disposed along sidewalls of the trench 2015) formed by removal of the etched-back sacrificial layer 1804B-1 at block 1609. Thus, in some cases, the second refill layer 2102T-1 may be described as being conformally deposited within the trenches 1915 and 2015. While a width of the trench 2015 is narrower than a width of the trench 1915, due to the presence of the etched-back first refill layer 1802B-1 disposed along sidewalls of the trench 2015, in some examples, the conformally deposited second refill layer 2102T-1 may not completely fill the trench 2015. In some embodiments, the second refill layer 2102T-1 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the second refill layer 2102T-1 may be described as including an SiN-like material. In various examples, the second refill layer 2102T-1 may be different than the first refill layer 1802B-1. In various examples, the second refill layer 2102T-1 may be deposited by a CVD process, an SACVD process, a flowable CVD process, an ALD process, a PVD process, and/or other suitable process.

The method 1600 proceeds to block 1612 where a third refill process is performed. Still with reference to FIGS. 20 and 21, in an embodiment of block 1612, a third refill process is used to form a third refill layer 2102T-2 over the device 1700, within the trenches 1915, 2015, and over the second refill layer 2102T-1 previously deposited at block 410, thereby filling the trenches 1915, 2015. In some embodiments, the third refill layer 2102T-2 may include SiO₂, SiN, SiCN, SiCON, SiCO, SiON, AlO, HfO, another HK material (e.g., having a dielectric constant K>=7), or a multi-layer composite refill material composed of a combination thereof. In some embodiments, the third refill layer 2102T-2 may also be described as including an SiN-like material. In various examples, the third refill layer 2102T-2 may be different than the second refill layer 2102T-1 and the first refill layer 1802B-1. In various examples, the third refill layer 2102T-2 may be deposited by a CVD process, an SACVD process, a flowable CVD process, an ALD process, a PVD process, and/or other suitable process. After formation of the third refill layer 2102T-2, a CMP process may be performed to remove excess material and planarize a top surface of the device 1700. Also, after formation of the third refill layer 2102T-2, the bottom portion 1913B is further defined, the bottom portion 1913B including the first refill layer 1802B-1, the second refill layer 2102T-1 over the first refill layer 1802B-1, and the third refill layer 2102T-2 over the second refill layer 2102T-1. In addition, after formation of the third refill layer 2102T-2, a top portion 1913T of a CPODE structure is defined, the top portion 1913T including the second refill layer 2102T-1 and the third refill layer 2102T-2. More specifically, after formation of the third refill layer 2102T-2, a CPODE structure 1913 (including the bottom portion 1913B and the top portion 1913T) is defined, where the CPODE structure 1913 is substantially the same as the CPODE structure 313, discussed above. It is also noted that the etch-back process of block 1608 further serves to define the depth ‘D2’ measured from the plane level with the top surface of a substrate mesa to a plane level with a bottom of the top portion 1913T. The total depth ‘D1’ of the CPODE structure 1913 is thus the sum of the depth ‘D2’ and the depth ‘D3’.

The method 1600 proceeds to block 1614 where subsequent processing is performed. For example, in some embodiments and after forming the CPODE structure 1913, a channel release process and replacement gate process may be performed to remove the dummy gate structure (including the dummy gate dielectric 508 and the dummy gate electrode 512) and the sacrificial layers 507, and replace them with a high-K/metal gate stack, such as described with reference to the semiconductor device 300. In some cases, after the channel release process and the replacement gate process, a CMG process may be performed to form a dielectric layer in a CMG region that isolates metal layers of adjacent structures, as also described above with reference to the semiconductor device 300. Thus, in some embodiments and after the block 1614, the semiconductor device 1700 may be substantially the same as the semiconductor device 300, discussed above.

While the method 1600 is described as first forming the CPODE structure 1913, then performing the channel release process and the replacement gate process, and then performing the CMG process, other embodiments are possible and within the scope of the present disclosure. For example, in some cases, the method 1600 may first perform the channel release process and the replacement gate process, followed by the CMG process, and then the CPODE structure 1913 may be formed. In other examples, the method 1600 may first perform the channel release process and the replacement gate process, followed by formation of the CPODE structure 1913, and then the CMG process may be performed. In still other embodiments, the method 1600 may first perform the CMG process, followed by formation of the CPODE structure 1913, and then the channel release process and the replacement gate process may be performed. In some cases, the method 1600 may first perform the CMG process, followed by performing the channel release process and the replacement gate process, and then the CPODE structure 1913 may be formed.

Generally, the semiconductor device 1700 may undergo further processing to form various features and regions known in the art. For example, subsequent processing may form contact openings, contact metal, as well as various contacts/vias/lines and multilayer interconnect features (e.g., metal layers and interlayer dielectrics) on the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 1600, and some process steps described above may be replaced or eliminated in accordance with various embodiments of the method 1600. Further, while the method 1600 has been shown and described as including the device 1700 having a GAA device, it will be understood that other device configurations are possible. In some embodiments, the method 1600 may be used to fabricate various types of devices such as planar transistor devices, FinFET devices, forksheet devices, CFET devices, and the like.

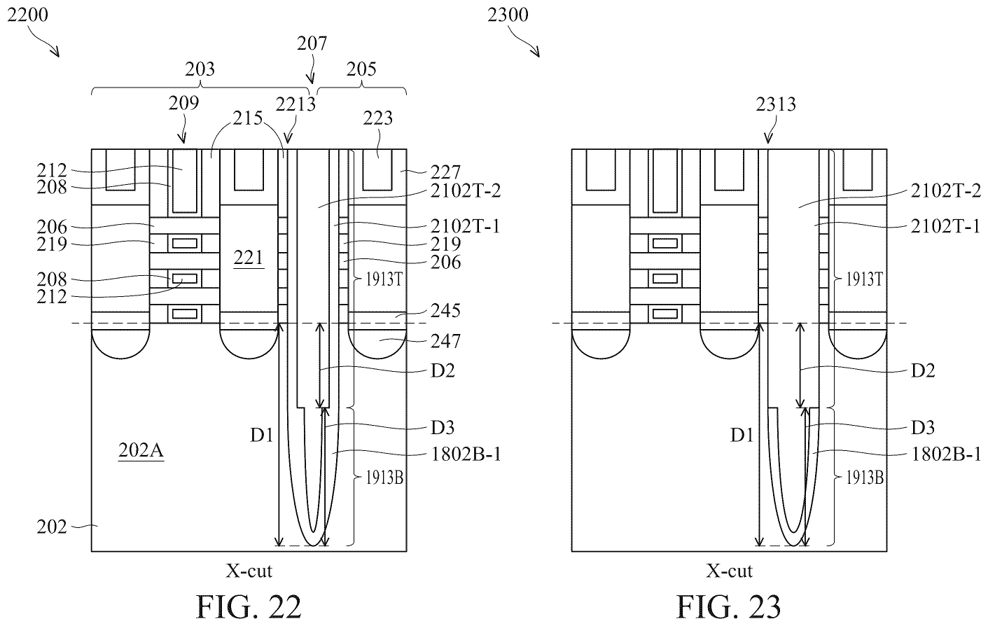

Once again, and previously noted, variations of the disclosed methods may be provided to fabricate semiconductor devices with CPODE structures of various other configurations. With respect to the method 1600, the process steps of the method may be modified to fabricate devices with a number of different CPODE structure configurations. For instance, reference is made to FIGS. 22-28, which illustrate embodiments of semiconductor devices fabricated in accordance with the method 1600 and having CPODE structures of varying configurations. As shown, the examples of FIGS. 22-28 include devices after the subsequent processing of block 1614 (e.g., after the channel release process and the replacement gate process, and including a high-K/metal gate stack).

With reference to FIG. 22, illustrated therein is a semiconductor device 2200, similar to the semiconductor devices 300, 1700 fabricated using the method 1600. However, the semiconductor device 2200 includes a different CPODE structure 2213. In particular, in the CPODE structure 2213, the second refill layer 2102T-1 is the same as the first refill layer 1802B-1. In contrast, in the CPODE structure 1913 of the semiconductor device 1700, the second refill layer 2102T-1 is different than the first refill layer 1802B-1.

With reference to FIG. 23, illustrated therein is a semiconductor device 2300, similar to the semiconductor devices 300, 1700 fabricated using the method 1600. However, the semiconductor device 2300 includes a different CPODE structure 2313. In particular, in the CPODE structure 2313, the second refill layer 2102T-1 is the same as the third refill layer 2102T-2. In contrast, in the CPODE structure 1913 of the semiconductor device 1700, the second refill layer 2102T-1 is different than the third refill layer 2102T-2.

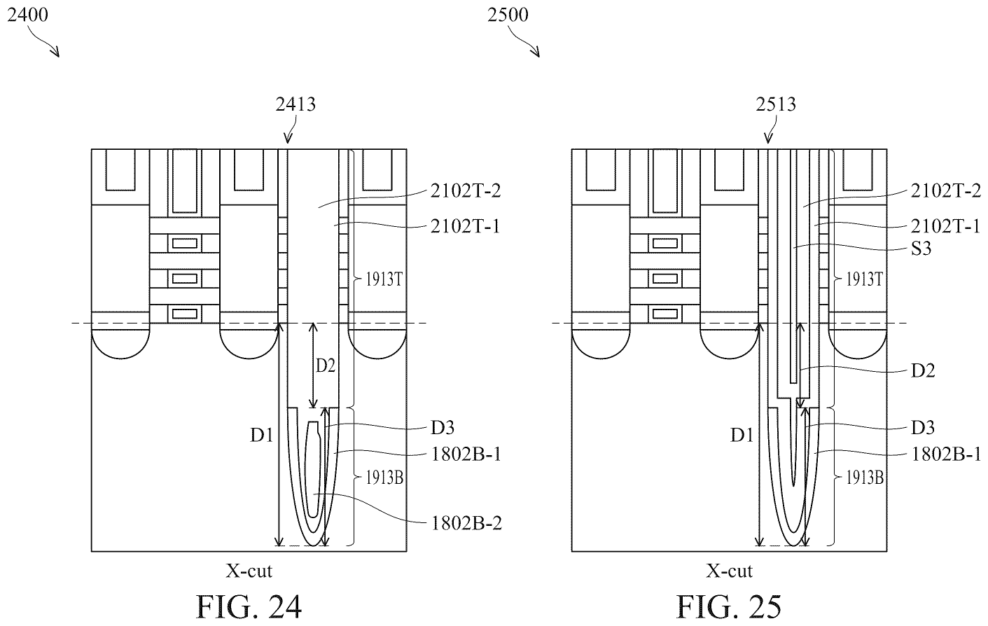

With reference to FIG. 24, illustrated therein is a semiconductor device 2400, similar to the semiconductor devices 300, 1700 fabricated using the method 1600. However, the semiconductor device 2400 includes a different CPODE structure 2413. In particular, in the CPODE structure 2413, the bottom portion 1913B includes one or more refill layers and an air gap. In the example shown, the bottom portion 1913B may include the first refill layer 1802B-1, the second refill layer 2102T-1, and an air gap 1802B-2. As described with reference to FIG. 21, the second refill layer 2102T-1 may be conformally deposited over the first refill layer 1802B-1 in the bottom portion 1913B. As noted, and in some examples, the conformal deposition of the second refill layer 2102T-1 may not completely fill the trench 2015. Thereafter, the third refill process is used to form the third refill layer 2102T-2. In particular, it is noted that deposition of the third refill layer 2102T-2 may be tuned (e.g., by appropriate selection of the materials and/or deposition processes used for the third refill layer 2102T-2) so that the third refill layer 2102T-2 is not deposited within the air gap 1802B-2. Stated another way, the air gap 1802B-2 may be substantially free of the third refill layer 2102T-2. It is also noted that in the CPODE structure 2413, the second refill layer 2102T-1 and the third refill layer 2102T-2 may be composed of the same material or of different materials. In various embodiments, inclusion of the air gap 1802B-2 reduces parasitic capacitance and may enhance performance of the device 2400. In some alternative embodiments, the bottom portion 1913B may only include the first refill layer 1802B-1 and the air gap 1802B-2. For example, in some cases, the deposition of the second refill layer 2102T-1 and the third refill layer 2102T-2 may be tuned (e.g., by appropriate selection of the materials and/or deposition processes used for the second refill layer 2102T-1 and the third refill layer 2102T-2) so that the second refill layer 2102T-1 and the third refill layer 2102T-2 are not deposited within the air gap 1802B-2. Stated another way, in such an example, the air gap 1802B-2 may be substantially free of both the second refill layer 2102T-1 and the third refill layer 2102T-2.

With reference to FIG. 25, illustrated therein is a semiconductor device 2500, similar to the semiconductor devices 300, 1700 fabricated using the method 1600. However, the semiconductor device 2500 includes a different CPODE structure 2513. In particular, in the CPODE structure 2513, the material selected for the third refill layer 2102T-2 includes a poor gap-fill material. The poor gap-fill material may be intentionally selected so as to form a seam S3 within the top portion 1913T. By way of illustration, the poor gap-fill material used for the third refill layer 2102T-2 may be deposited as part of the third layer refill process of block 1612 of the method 1600. In some embodiments, inclusion of the seam S3 may reduce parasitic capacitance and enhance performance of the device 2500.

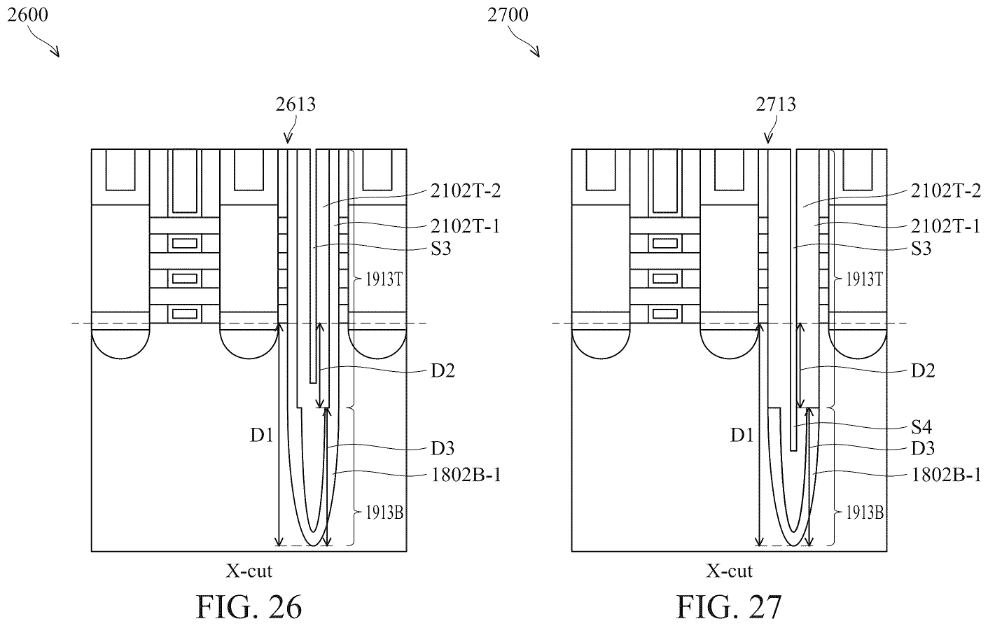

With reference to FIG. 26, illustrated therein is a semiconductor device 2600, similar to the semiconductor devices 300, 1700 fabricated using the method 1600. However, the semiconductor device 2600 includes a different CPODE structure 2613. In an example, the CPODE structure 2613 may be a combination of aspects of the embodiments illustrated in FIGS. 22 and 25. For example, in the CPODE structure 2613, the second refill layer 2102T-1 is the same as the first refill layer 1802B-1 (e.g., like the embodiment of FIG. 22). In addition, the material selected for the third refill layer 2102T-2 includes a poor gap-fill material, resulting in the seam S3 within the top portion 1913T (e.g., like the embodiment of FIG. 25).

With reference to FIG. 27, illustrated therein is a semiconductor device 2700, similar to the semiconductor devices 300, 1700 fabricated using the method 1600. However, the semiconductor device 2700 includes a different CPODE structure 2713. In an example, in the CPODE structure 2713, the materials selected for the second refill layer 2102T-1 and the third refill layer 2102T-2 include poor gap-fill materials. The poor gap-fill material may be intentionally selected so as to form the seam S3 within the top portion 1913T and a seam S4 within the bottom portion 1913B. By way of illustration, the poor gap-fill material used for the second refill layer 2102T-1 may be deposited as part of the second refill process of block 1610 of the method 1600, and the third refill layer 2102T-2 may be deposited as part of the third layer refill process of block 1612 of the method 1600. In some embodiments, inclusion of the seams S3, S4 may reduce parasitic capacitance and enhance performance of the device 2700. It is noted that in the CPODE structure 2713, the second refill layer 2102T-1 and the third refill layer 2102T-2 may be composed of the same material or of different materials. Also, in at least some cases, instead of separately depositing both the second refill layer 2102T-1 and the third refill layer 2102T-2, blocks 1610 and 1612 may be combined into a single deposition of a poor gap-fill refill material, the single deposition effectively forming both of the seams S3, S4.

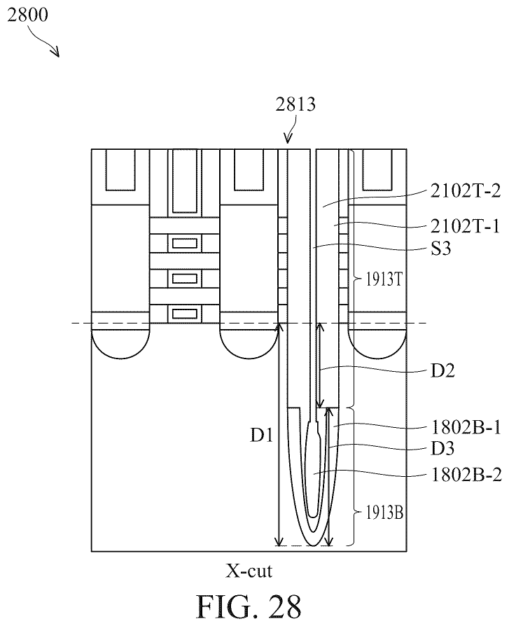

With reference to FIG. 28, illustrated therein is a semiconductor device 2800, similar to the semiconductor devices 300, 1700 fabricated using the method 1600. However, the semiconductor device 2800 includes a different CPODE structure 2813. In an example, the CPODE structure 2813 may be a combination of aspects of the embodiments illustrated in FIGS. 24 and 27. For example, in the CPODE structure 2813, the bottom portion 1913B may include the first refill layer 1802B-1, the second refill layer 2102T-1, and the air gap 1802B-2 (e.g., like the embodiment of FIG. 24). In some alternative embodiments, and as noted with reference to the embodiment of FIG. 24, the bottom portion 1913B may only include the first refill layer 1802B-1 and the air gap 1802B-2. Further, in the CPODE structure 2813, the material selected for the third refill layer 2102T-2 includes a poor gap-fill material, resulting in the seam S3 within the top portion 1913T (e.g., like the embodiment of FIG. 27). In some cases, the materials selected for both the second refill layer 2102T-1 and the third refill layer 2102T-2 include poor gap-fill materials. It is also noted that in the CPODE structure 2813, the second refill layer 2102T-1 and the third refill layer 2102T-2 may be composed of the same material or of different materials. Also, in at least some cases, instead of separately depositing both the second refill layer 2102T-1 and the third refill layer 2102T-2, blocks 1610 and 1612 may be combined into a single deposition of a poor gap-fill refill material, such as when the bottom portion 1913B only includes the first refill layer 1802B-1 and the air gap 1802B-2, the single deposition effectively forming the seam S3 while preserving the air gap 1802B-2.

With respect to the description provided herein, disclosed are structures and related methods of forming a CPODE structure (or dielectric plug), with multiple dielectric layers of varying material composition stacked at least partially in a vertical direction, to provide leakage current reduction. In an example, the CPODE refill material used to refill a bottom portion of the CPODE structure (bottom CPODE refill material) may include a single layer or multiple layers and is selected to include a fixed-charge free material. In some embodiments, the CPODE refill material and/or number of layers used to refill a top portion of the CPODE structure (top CPODE refill material) may be different from the bottom CPODE refill material and/or number of layers. To be sure, in some cases the bottom CPODE refill material and the top CPODE refill material may both include at least one layer formed of the same material. In some embodiments, the bottom CPODE refill material includes an SiO-like material, and the top CPODE refill material includes an SiN-like material. In some embodiments, the bottom CPODE refill material may be buried below a plane defined by a top surface of a neighboring STI region, and the overall depth of the disclosed CPODE structure may be deeper than (or in some cases, shallower than) neighboring STI regions. In various examples, the bottom CPODE refill material is selected to provide leakage current reduction, and the top CPODE refill material is selected to mitigate loss (e.g., such as may occur in existing implementations during removal of a dummy poly gate). By employing the disclosed CPODE process and related structure(s), device performance and reliability of transistors formed in the adjacent active regions will be enhanced. Those of skill in the art will readily appreciate that the methods and structures described herein may be applied to a variety of other semiconductor devices to advantageously achieve similar benefits from such other devices without departing from the scope of the present disclosure.

Thus, one of the embodiments of the present disclosure described a method including providing a partially-fabricated semiconductor device including a dummy gate structure disposed over a semiconductor layer stack. In some embodiments, the method further includes removing the dummy gate structure and at least a portion of each semiconductor layer of the semiconductor layer stack to form a trench. In some examples, the method further includes forming one or more refill layers in a bottom portion of the trench and forming one or more refill layers in a top portion of the trench over the bottom portion of the trench. In some embodiments, the one or more refill layers in the top and bottom portions of the trench respectively define top and bottom portions of an isolation structure. In some examples, at least one refill layer of respective ones of the top and bottom portions of the isolation structure have a different material composition.

In another of the embodiments, discussed is a method including forming a trench through a dummy device structure in an isolation region of a substrate. In some embodiments, the method further includes forming, in a bottom portion of the trench, a first refill layer and a sacrificial layer over the first refill layer. In some examples, after removing the sacrificial layer to expose the first refill layer, the method further includes conformally depositing a second refill layer within the bottom portion of the trench over the exposed first refill layer and within a top portion of the trench. In some embodiments, the method further includes forming a third refill layer within the top and bottom portions of the trench including over the second refill layer. In some examples, the first, second, and third refill layers in the top and bottom portions of the trench provide an isolation structure in the isolation region. In some embodiments, the first refill layer is composed of a different material than at least one of the second and third refill layers.

In yet another of the embodiments, discussed is a semiconductor device including an active region and an isolation structure disposed in an isolation region defined at a boundary of the active region. In some embodiments, the isolation structure includes a bottom portion and a top portion disposed over the bottom portion. In some examples, the bottom portion includes a first refill layer, and the top portion includes second and third refill layers. In some embodiments, the first refill layer is composed of a different material than at least one of the second and third refill layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a trench through a dummy gate structure along an active edge, wherein a first depth of the trench is greater than a second depth of an adjacent shallow trench isolation (STI) feature; and
forming a dielectric plug in the trench, wherein the dielectric plug includes at least two portions stacked in a vertical direction, and wherein the forming the dielectric plug comprises:
forming one or more dielectric layers in a bottom portion of the trench to define a first portion of the at least two portions of the dielectric plug; and
forming one or more dielectric layers in a top portion of the trench stacked in the vertical direction over the bottom portion of the trench to define a second portion of the at least two portions of the dielectric plug;
wherein at least one dielectric layer of the one or more dielectric layers formed in the bottom portion of the trench is different than at least one dielectric layer of the one or more dielectric layers formed in the top portion of the trench.

2. The method of claim 1, wherein the forming the trench is performed prior to performing a channel release process and a replacement gate process.

3. The method of claim 1, wherein the forming the trench is performed after performing a channel release process and a replacement gate process.

4. The method of claim 1, wherein the one or more dielectric layers formed in the bottom portion of the trench include an SiO-like material, and wherein the one or more dielectric layers formed in the top portion of the trench include an SiN-like material.

5. The method of claim 1, wherein the one or more dielectric layers formed in the bottom portion of the trench include a fixed-charge free material.

6. The method of claim 1, wherein each of the one or more dielectric layers formed in the bottom portion of the trench are different from each other, wherein each of the one or more dielectric layers formed in the top portion of the trench are different from each other, and wherein each of the one or more dielectric layers formed in the bottom portion of the trench are different from each of the one or more dielectric layers formed in the top portion of the trench.

7. The method of claim 1, wherein at least one dielectric layer of the one or more dielectric layers formed in the bottom portion of the trench is the same as at least one dielectric layer of the one or more dielectric layers formed in the top portion of the trench.

8. The method of claim 1, wherein at least one of the first and second portions of the at least two portions includes an air gap or a seam.

9. The method of claim 1, wherein the second portion of the at least two portions of the dielectric plug extends deeper into an underlying substrate than a top surface of the adjacent STI feature.

10. The method of claim 1, wherein a bottom surface of the adjacent STI feature extends deeper into an underlying substrate than the second portion of the at least two portions of the dielectric plug.

11. A method, comprising:
performing an etching process at a boundary between active regions to define a trench that extends deeper into an underlying substrate than a shallow trench isolation (STI) feature disposed in at least one of the active regions;
forming a first dielectric layer along sidewalls of a bottom part of the trench;
forming a second dielectric layer along sidewalls of a top part of the trench, wherein the second dielectric layer extends into the bottom part of the trench; and
forming a third dielectric layer in the top part of the trench between the second dielectric layer on the sidewalls of the top part of the trench, wherein the third dielectric layer extends into the bottom part of the trench;
wherein the first dielectric layer, the second dielectric layer, and the third dielectric layer collectively define a dielectric plug, and wherein the first dielectric layer is different than at least one of the second and third dielectric layers.

12. The method of claim 11, further comprising:
prior to forming the second dielectric layer, forming a sacrificial layer over the first dielectric layer;
etching-back the first dielectric layer and the sacrificial layer; and
removing the etched-back sacrificial layer.

13. The method of claim 11, wherein the first dielectric layer includes an SiO-like material, and wherein the second and third dielectric layers include an SiN-like material.

14. The method of claim 11, wherein the first dielectric layer is the same as the second dielectric layer.

15. The method of claim 11, wherein the second dielectric layer is the same as the third dielectric layer.

16. The method of claim 11, wherein the first dielectric layer includes a fixed-charge free material.

17. The method of claim 11, wherein the dielectric plug includes an air gap, a seam, or a combination thereof.

18. A semiconductor device, comprising:
a first active region interfacing a second active region along an active edge; and
a dielectric plug disposed along the active edge;
wherein the dielectric plug comprises:
a first dielectric layer disposed along sidewalls of a bottom part of the dielectric plug;
a second dielectric layer disposed along sidewalls of a top part of the dielectric plug, wherein the second dielectric layer extends into the bottom part of the dielectric plug; and
a third dielectric layer in the top part of the dielectric plug between the second dielectric layer on the sidewalls of the top part of the dielectric plug, wherein the third dielectric layer extends into the bottom part of the dielectric plug;
wherein the first dielectric layer is different than at least one of the second and third dielectric layers.

19. The semiconductor device of claim 18, wherein the dielectric plug includes an air gap, a seam, or a combination thereof.

20. The semiconductor device of claim 18, further including a shallow trench isolation (STI) feature disposed in at least one of the first and second active regions, wherein the dielectric plug extends deeper into an underlying substrate than the STI feature.
